(19) United States
(12) Patent Application Publication
(10) Pub. No.: US 2025/0298323 A1
(43) Pub. Date: Sep. 25, 2025

(54) COMPUTER IMPLEMENTED METHOD, COMPUTER-READABLE MEDIUM, COMPUTER PROGRAM PRODUCT AND CORRESPONDING SYSTEMS FOR GENERATING AERIAL IMAGES OF PHOTOLITHOGRAPHY MASKS

(71) Applicant: Carl Zeiss SMT GmbH, Oberkochen (DE)

(72) Inventors: Martin van Driel, Muenchen (DE); Niklas Georg, Haiger (DE)

(21) Appl. No.: 19/231,674

(22) Filed: Jun. 9, 2025

Related U.S. Application Data
(63) Continuation-in-part of application No. PCT/EP2023/087651, filed on Dec. 22, 2023.

(30) Foreign Application Priority Data
Dec. 29, 2022 (DE) 102022135019.3

(51) Int. Cl. G03F 7/00

(52) U.S. Cl. CPC G03F 7/705; G03F 7/70666

(57) ABSTRACT

The invention relates to a computer implemented method for generating an aerial image of a model of a photolithography mask under illumination by incident electromagnetic waves, the method comprising: a) Approximately simulating the propagation of the incident electromagnetic waves within a first section of the photolithography mask that comprises multiple structures; b) Simulating the propagation of the simulated electromagnetic waves from step a) within a second section of the photolithography mask analytically or numerically; c) Simulating a representation of an electromagnetic near field of the model of the photolithography mask by propagating the simulated electromagnetic waves from step b) to a near field plane; and d) Generating an aerial image of the photolithography mask.

### CROSS-REFERENCE TO RELATED APPLICATIONS

This application is a continuation-in-part of and claims benefit under 35 U.S.C. § 120 from PCT Application No. PCT/EP2023/087651, filed on Dec. 22, 2023, which claims priority from German patent application 10 2022 135 019.3, filed on Dec. 29, 2022. The entire contents of each of these earlier applications are incorporated herein by reference.

### TECHNICAL FIELD

The invention relates to a computer implemented method, a computer-readable medium, a computer program product and corresponding systems for generating aerial images of photolithography masks. The method, computer-readable medium, computer program product and systems can be utilized for quantitative metrology, defect detection in photolithography masks, assessment of defect relevance in photolithography masks, for photolithography mask improvement, for system simulation or for process control, process monitoring or process improvement.

### BACKGROUND

A wafer made of a thin slice of silicon serves as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patterns are subject to several influences. One of the most crucial steps is the photolithography process.

Photolithography is a process used to produce patterns on the substrate of a wafer. The patterns to be printed on the surface of the substrate are usually generated by computer-aided-design (CAD). From the design, for each layer a photolithography mask is generated, which contains a magnified image of the computer-generated pattern to be etched into the substrate. The photolithography mask can be further adapted, e.g., by use of optical proximity correction techniques. During the printing process an illuminated image projected from the photolithography mask is focused onto a photoresist thin film formed on the substrate. A semiconductor chip powering mobile phones or tablets comprises, for example, approximately between 80 and 120 patterned layers. In the past, when photolithography required less precision, the circuit layout equaled the mask pattern which equaled the wafer pattern.

Due to the growing integration density in the semiconductor industry, photolithography masks have to image increasingly smaller structures onto wafers. The aspect ratio and the number of layers of integrated circuits constantly increases and the structures are growing into 3^{rd} (vertical) dimension. The current height of the memory stacks is exceeding a dozen of microns. In contrast, the feature size is becoming smaller. The minimum feature size or critical dimension is below 10 nm, for example 7 nm or 5 nm, and is approaching feature sizes below 3 nm in near future. While the complexity and dimensions of the semiconductor structures are growing into the 3^{rd} dimension, the lateral dimensions of integrated semiconductor structures are becoming smaller. Producing the small structure dimensions imaged onto the wafer requires photolithography masks or templates for nanoimprint photolithography with ever smaller structures or pattern elements. The production process of photolithography masks and templates for nanoimprint photolithography is, therefore, becoming increasingly more complex and, as a result, more time-consuming and ultimately also more expensive. With the advent of EUV photolithography scanners, the nature of masks changed from transmission-based patterning to reflection-based patterning.

Today, the minimum feature size on the mask has reached sub-wavelength dimensions. Consequently, the so-called optical proximity effect caused by non-uniformity of energy intensity due to optical diffraction during the exposure process occurs. As a result, images formed on the substrate do not faithfully reproduce the patterns on the photolithography mask.

Therefore, many applications require an aerial image of the photolithography mask, which simulate the radiation intensity distribution at the substrate level. In this way, the aerial image allows for an analysis of the semiconductor structures that will be printed onto the substrate during the printing process. However, the generation of an aerial image is time-consuming and expensive. Therefore, methods for generating aerial images based on a model of a photolithography mask have become important.

Among these methods, there are time-consuming rigorous simulations such as finite difference time domain (FDTD) or rigorous coupled wave analysis (RCWA), and fast approximations such as the thin element approximation (TEA). Due to the heavy computational load for full-chip applications, rigorous simulation is not typically used in commercial computational photolithography software. The thin element approximation (TEA) assumes that the thickness of the structures on the photolithography mask is very small compared to the wavelength, and that the widths of the structures on the photolithography mask are very large compared to the wavelength. However, as lithographic processes use radiation of shorter and shorter wavelengths, and the structures on the patterning device become smaller and smaller and grow into the vertical dimension, these assumptions do not hold anymore. Interaction of the incoming radiation with the absorber structures leads to mask 3D effects, which must be taken into account by the simulation. Therefore, the TEA yields inaccurate aerial images for radiation of short wavelength.

A typical mask 3D effect is, for example, mask shadowing. The chief ray angle specifies the angle between the optical axis and the normal vector of the mask surface. The present EUV projection systems, for example, employ a CRA of 6°. Mask shadowing occurs due to the height of the absorber structures and the non-telecentric illumination at mask level, which modulates the captured intensity from the shadowed mask area through the reflective optics onto the wafer. At the wafer level, this causes asymmetric shadowing, an image shift and size bias depending on the feature orientation and a shift of the process window.

Another mask 3D effect are phase shifts caused by the diffraction at the absorber structures. These phase effects generate imaging effects, which are very similar to phase deformations caused by wave aberrations of the projection systems.

Another mask 3D effect can be attributed to the reflective character of EUV photolithography masks. The dominant part of the reflected light originates from the multilayer, which is designed to provide a high reflectivity over a sufficiently large range of incidence angles. However, there is also some reflected light from the top of the absorber causing double images.

These mask 3D effects should not be ignored during the lithography process. However, rigorous simulations methods such as finite difference time domain (FDTD) or rigorous coupled wave analysis (RCWA) that take into account mask 3D effects are computationally not feasible.

Therefore, there is a need for an accurate and fast simulation method for aerial images of photolithography masks, which takes into account at least some of the mask 3D effects.

A known method for generating an aerial image of a photolithography mask is disclosed in WO 2019/214909 A1. The method comprises generating one or more electromagnetic field determination expressions based on the Maxwell Equations and the Quantum Schrodinger Equation. The method comprises determining an electromagnetic field by propagating electromagnetic waves through a mask stack region of interest based on the Maxwell Equations and the Quantum Schrödinger Equation.

It is an objective of the invention to obtain an alternative generation method for aerial images. It is a further objective of the invention to generate aerial images with high accuracy. In particular, it is an objective of the invention to account for mask 3D effects during the generation of aerial images. It is a further objective of the invention to generate aerial images requiring low computation times. It is another objective of the invention to obtain an aerial image generation method which is applicable to transmission-based and reflection-based photolithography masks. It is another objective of the invention to make the resolution of the aerial image independent from the smallest design feature. It is another objective of the invention to make the resolution of sub-pixel design features possible. It is another objective of the invention to allow for a more flexible representation of the photolithography masks. A further objective of the invention is to improve photolithography mask design without the need to actually print a wafer. Another objective of the invention is to detect defects or placement-errors in photolithography masks or to measure structures on the photolithography mask with high accuracy and at low computation times. Another objective of the invention is to assess the relevance of defects detected in photolithography masks with high accuracy and at low computation times.

The objectives are achieved by the invention specified in the independent claims. Advantageous embodiments and further developments of the invention are specified in the dependent claims.

### SUMMARY

Embodiments of the invention concern computer implemented methods, a computer-readable medium, a computer program product, and corresponding systems for generating aerial images of photolithography masks or for detecting defects and assessing the relevance of defects in photolithography masks.

An embodiment of the invention involves a computer implemented method for generating an aerial image of a model of a photolithography mask under illumination by incident electromagnetic waves. The method comprises: a) Approximately simulating the propagation of the incident electromagnetic waves within a first section of the photolithography mask that comprises multiple structures; b) Simulating the propagation of the simulated electromagnetic waves from step a) within a second section of the photolithography mask analytically or numerically; c) Simulating a representation of an electromagnetic near field within the model of the photolithography mask by propagating the simulated electromagnetic waves from step b) to a near field plane; and d) Generating an aerial image of the photolithography mask by applying a simulation of an imaging process of a photolithography system or metrology system to the representation of the electromagnetic near field.

The method can be used for various purposes, e.g., for improving the model, e.g., a design pattern, of the photolithography mask, for repairing the photolithography mask, for determining the quality of the photolithography mask, for taking measurements of the photolithography mask, for detecting or assessing defects in the photolithography mask, for selecting an illumination setting for the photolithography system, for source-mask optimization or inverse photolithography.

According to an embodiment of the invention, in particular concerning transmission-based photolithography masks, e.g., DUV photolithography masks, the simulated electromagnetic waves are incident on a base plane of the photolithography mask, propagated through the second section of the photolithography mask and subsequently through the first section of the photolithography mask to the near field plane.

According to an embodiment of the invention, in particular concerning reflection-based photolithography masks, e.g., EUV photolithography masks, the second section comprises a multilayer in the form of a stack of optical thin films for reflecting the electromagnetic waves, and the simulated electromagnetic waves are incident on a structure plane, propagated through the first section of the photolithography mask, reflected within the multilayer in the second section of the photolithography mask and propagated back through the first section of the photolithography mask to the structure plane and to the near field plane. Thus, according to the embodiment of the invention the electromagnetic waves are propagated through the first section, are subsequently reflected by the second section and are again propagated through the first section of the photolithography mask to the near field plane.

According to an embodiment of the invention concerning reflection-based measurements of DUV photolithography masks, the second section contains a mask carrier that comprises a glass substrate, and the simulated electromagnetic waves are incident on a structure plane delimiting the first section from the outside, the electromagnetic waves are partially reflected by the structure plane, and partially propagated through the first section of the photolithography mask, partially reflected by the mask carrier of the photolithography mask and propagated through the first section of the photolithography mask.

In each of the aforementioned embodiments, further reflections and interference effects at other material interfaces can also be taken into account.

The term “photolithography mask” refers to a generic patterning device that can be used to endow an incoming radiation beam with a patterned cross-section, corresponding to a pattern that is to be created in a target portion of a substrate.

The photolithography mask may have an aspect ratio of between 1:1 and 1:4, preferably between 1:1 and 1:2, most preferably of 1:1 or 1:2. The photolithography mask may have a nearly rectangular shape. The photolithography mask may be preferably 5 to 7 inches long and wide, most preferably 6 inches long and wide. Alternatively, the photolithography mask may be 5 to 7 inches long and 10 to 14 inches wide, preferably 6 inches long and 12 inches wide.

A “model” of a photolithography mask refers to a representation of the photolithography mask or a section thereof. The model can, for example, comprise a computer readable file, such as a computer assisted design (CAD) file or a graphic design system (GDS) file, or a technical drawing, a set of polygons representing the structures of the photolithography mask or a section thereof. A model of a photolithography mask can comprise material information, e.g., complex refractive indices of materials contained in the photolithography mask, electric permittivities, magnetic permeabilities, or derived representations. A model of a photolithography mask can comprise parameters describing dimensions of structures in the photolithography mask, e.g., the thicknesses of the layers in the multilayer of an EUV mask or the thickness of absorber layers, or the dimension of the absorber structures.

A model of a photolithography mask can comprise parameters describing the location of structures in the photolithography mask, e.g., the location of absorber structures or layers in the multilayer. A model of a photolithography mask can comprise parameters describing the shape of structures in the photolithography mask, e.g., the shape of the absorber structures such as side wall angles or corner rounding, etc. A model of a photolithography mask can comprise an image, e.g., a 2D image or a 3D image (e.g., a volume of voxels or a number of 2D slices of a volume), that represents properties of the photolithography mask. The image can contain one, two or more channels. The image can comprise image elements, e.g., pixels or voxels. The properties of the photolithography mask can comprise material properties, e.g., refractive indices, electric permittivities, magnetic permeabilities, or derived representations. A model of a photolithography mask can comprise descriptions of the structures within the photolithography mask, e.g., in the form of curves, contours, polygons, Splines, NURBS, Bézier curves, etc.

The model of the photolithograph mask preferably describes the photolithography mask at least partially in a dimension orthogonal to a base plane of the photolithography mask. The model of the photolithography mask can comprise one or more different sections of the photolithography mask or parts thereof, for example the first section and/or the second section. The one or more different sections can be arranged at different depths with respect to the normal of the surface.

The first section of the photolithography mask comprises multiple structures. These structures can be arranged in a design pattern or model that determines the patterns imprinted on the wafer during the printing process. The design pattern or model can comprise structures and non-structures, in particular absorber structures and non-absorber structures. The second section of the photolithography mask can contain a mask carrier that can comprise one or multiple layers of one or more materials. The structures and the non-structures can be deposited on the mask carrier. The mask carrier can comprise a substrate layer. The second section can be configured to transmit the incident electromagnetic waves (for transmission-based photolithography masks) or it can be configured to reflect the incident electromagnetic waves (for reflection-based photolithography masks). The first section can be directly adjacent to the second section of the photolithography mask. Thus, the first section and the second section can have a common boundary, e.g., a boundary plane. The mask carrier in the photolithography mask can be delimited by the boundary plane and a base plane. The boundary plane can be a surface plane of the mask carrier. The base plane is preferably parallel to the boundary plane. The base plane can delimit the second section from the outside. It can form an interface between the mask carrier and the outside of the photolithography mask through which the electromagnetic waves propagate. The structures in the first section of the photolithography mask can be delimited by the boundary plane and a structure plane. The structure plane can delimit the first section of the photolithography mask from the outside. The structure plane can contain the portion of the surface of the structures, which is facing away from the boundary plane. Preferably, the structure plane is parallel to the boundary plane. The first section of the photolithography mask can extend between the structure plane and the boundary plane and can be delimited by these planes. The second section of the photolithography mask can extend between the boundary plane and the base plane. It can be delimited by the boundary plane and the base plane. The second section can contain a stack of homogeneous parallel layers. Homogeneous means that the material properties do not change within a layer. Other constructions of photolithography masks containing a first section and a second section can also be used.

An electromagnetic near field indicates the distribution of the electromagnetic waves in a near field plane. The near field plane can be located next to a structure plane of the photolithography mask that delimits the first section of the photolithography mask from the outside. Preferably, the near field plane is parallel to the structure plane of the photolithography mask. The near field plane can be located anywhere between the structure plane and a wafer plane, for example, the near field plane can be located at a distance between 0 and 1000 nm from the structure plane, preferably at a distance between 0 and 100 nm, more preferably at a distance between 0 and 50 nm, even more preferably at a distance between 0 and 20 nm and most preferably at a distance between 0 and 10 nm. In a preferred embodiment of the invention the near field plane and the structure plane are identical. The near field plane could, in principle, also lie within the first section, within the second section, on the structure plane, on the base plane, or outside of the photolithography mask at the side of the base plane of the photolithography mask, for example in case the electromagnetic waves are re-propagated back into the photolithography mask after propagation through the first section.

A representation of an electromagnetic (near) field can refer to the (complex) electric field E or the (complex) scattered electric field E_{sc}=E−E_{inc}, where E_{inc} denotes the incident electric field. A complex electromagnetic field can be represented for example, in terms of the real and imaginary part, or the amplitude and phase, etc. A representation of an electromagnetic field can refer to the (complex) magnetic field H or the (complex) scattered magnetic field H_{sc}=H−H_{inc}, where H_{inc} denotes the incident magnetic field. A representation of an electromagnetic field can comprise the envelope of the total or scattered electric field or of the total or scattered magnetic field, for example the total electric field envelope

$$\frac{E}{{e}^{- ik} {inc}^{\cdot r}}$$

where the fast-varying electric field is demodulated by the fast-varying component e^{-ik}^{_{inc}}^{·r}, k_{inc} denotes the incident wave-vector and r the spatial coordinate vector. The envelope is finally multiplied with the phase term to obtain the electric field E. A representation of an electromagnetic field can comprise measurements derived from the electromagnetic field, e.g., diffraction orders, the spectrum, the far field or the intensity field, etc. A representation of an electromagnetic field within the photolithography mask can refer to the electromagnetic field within the photolithography mask, to a section of the electromagnetic field within the photolithography mask, to an electromagnetic field next to the photolithography mask, e.g., a near field, etc. A representation of an electromagnetic field can comprise representations of the electromagnetic field for different spatial directions. For example, a representation of an electromagnetic field can comprise a 2D or 3D image containing one, two or more channels, such that the 2D or 3D image comprises a representation of the electromagnetic field in each spatial direction, e.g., the complex electric field in x and y or in x, y and z directions yielding a 2D or 3D image with four or six channels.

An aerial image indicates the radiation intensity distribution in a wafer plane. It is generated from the representation of an electromagnetic near field by applying a simulation of an imaging process of a photolithography system or metrology system to the representation of the electromagnetic near field.

An optical metrology system refers to a system which measures an aerial image of at least a part of a photolithography mask, or quantities which can be derived from the aerial image, for example critical dimension (CD), normalized image log-slope (NILS), edge placement, defects, etc.

In case of a photolithography system, a wafer plane refers to a plane within the resist on top of a wafer if the wafer was placed in the photolithography system. In case of an optical metrology system, a wafer plane refers to a plane in which the camera sensors are located.

The electromagnetic near field is computed in different ways within the first section of the photolithography mask and within the second section of the photolithography mask. Within the first section several assumptions described below can be made in the photolithography setting, which allow for a simplified and fast computation of the propagation of the electromagnetic waves within the first section. The propagation of the electromagnetic waves within the first section is computed by use of a wave propagation method, which takes into account the inhomogeneity of the medium within the first section of the photolithography mask. Within the second section, the propagation of the electromagnetic waves is computed analytically or numerically. In this way, a highly accurate approximation of the propagation of the electromagnetic waves within the photolithography mask is obtained, requiring computation times several magnitudes below rigorous simulation methods. Thus, the simulation of electromagnetic near fields and aerial images within industry applications becomes feasible.

According to a first example of the embodiment, the propagation of the incident electromagnetic waves within the first section of the photolithography mask in step a) is approximately simulated using a Helmholtz equation. In this way, the approximation is simplified and, thus, the complexity and the computation time reduced.

According to a second example of the embodiment, the propagation of the incident electromagnetic waves within the first section of the photolithography mask in step a) is approximately simulated using a machine learning model. By using a machine learning model, the computation time can be strongly reduced, as after training a single and fast forward pass is sufficient to compute the propagation of the incident electromagnetic waves.

According to an aspect of the first example, the Helmholtz equation is approximated using a forward Helmholtz equation. In this way, the approximation is simplified and, thus, the complexity and the computation time reduced.

The forward Helmholtz equation can be solved using a beam propagation method. In this way, the approximation is simplified and, thus, the complexity and the computation time reduced.

In a preferred embodiment, the forward Helmholtz equation is solved using a wave propagation method that approximately describes the propagation of electromagnetic waves through an inhomogeneous medium. By using the wave propagation method the forward Helmholtz equation is solved quickly, thereby reducing the computation time of the method. Furthermore, by taking into account the inhomogeneity of the first section of the photolithography mask, e.g., due to different materials in absorber structures and non-absorber structures, the wave propagation is simulated with high accuracy.

According to an aspect of the preferred embodiment, the first section of the photolithography mask is decomposed into different materials by defining a characteristic function for each material that indicates the presence of the material within different locations in the first section of the photolithography mask, wherein at least one characteristic function is non-binary. This allows for a more general representation of the material distribution within the first section of the photolithography mask, such that intermediate material properties can be represented as weighted average of the discrete materials. Such intermediate values can occur for example, when an effective material representation is used to approximate the interaction of sharp contrasts with electromagnetic waves. This can be used as a mathematical means for describing the material distribution that leads to improved simulation results and, thus, to more accurate aerial images.

In an example, the characteristic functions form an affine combination at each location in the first section of the photolithography mask. An affine combination of functions is a linear combination, such that the sum of all functions at each location amounts to 1. This ensures mathematically, that at each location the sum over all materials amounts to 1.

In an example, the characteristic functions are band-limited. This allows for selecting a sampling grid of lower resolution than required for binary characteristic functions. In this way, the computation time of the method is reduced.

In an example, a low pass filter is applied to the characteristic functions. This allows for a fast computation of band-limited characteristic functions.

Applying the low pass filter can comprise applying a spatial analytical Fourier transform to the characteristic functions followed by an inverse Fourier Transform. In this way, the low pass filter can be applied quickly at a reduced computation time of the method.

In an example, the wave propagation method approximates an analytical Fourier Transform by a Fast Fourier Transform and/or an analytical inverse Fourier Transform by a Fast Inverse Fourier Transform, thereby reducing the computation time of the method.

According to an aspect, the wave propagation method approximates an analytical Fourier Transform by a Fast Fourier Transform, and the wave propagation method takes into account the angle of the incident electromagnetic waves by assuming quasiperiodic boundary conditions in the Fast Fourier Transform at one or more pairs of opposite boundaries perpendicular to a base plane of the photolithography mask. In this way, the accuracy of the approximation of the electromagnetic wave propagation is improved.

In an example, the electromagnetic waves within the first section have a dispersion relation that depends on the angle of the incident electromagnetic waves. Preferably, the dispersion relation within the first section is modified by a phase shift in the coordinates parallel to the base plane of the photolithography mask. In this way, the accuracy of the approximation of the electromagnetic wave propagation is improved.

The photolithography mask can be a transmission-based photolithography mask or a reflection-based photolithography mask.

In case of a reflection-based photolithography mask, the second section comprises a multilayer in the form of a stack of optical thin films for reflecting the electromagnetic waves. According to an aspect, simulating the reflection of the electromagnetic waves within the multilayer comprises the analytical or numerical computation of reflection coefficients at a boundary between the second section and the first section of the photolithography mask, the reflection coefficients describing the propagation of the electromagnetic waves within the stack of optical thin films of the multilayer. Instead of iteratively propagating the electromagnetic waves through each layer of the multilayer, reflection coefficients at the boundary only have to be computed once to simulate the reflection within the multilayer. In this way, a highly accurate simulation of the electromagnetic wave propagation within the multilayer is obtained at a strongly reduced computation time.

According to an aspect, the reflection coefficients at the boundary are computed separately within the structures and outside the structures in the first section of the photolithography mask. In this way, the accuracy of the electromagnetic wave propagation is improved.

In an example, simulating the propagation of the simulated electromagnetic waves within the second section of the photolithography mask comprises applying the reflection coefficients to the electromagnetic waves incident on the boundary. In this way, a fast and accurate simulation within the second section is obtained.

According to a preferred embodiment of the invention, the method for generating an aerial image of a model of a photolithography mask further comprises adjusting at least one parameter of the method to minimize dissimilarities between one or more reference aerial images of the photolithography mask and corresponding one or more generated aerial images of the model of the photolithography mask, wherein the at least one parameter is from the group comprising mask parameters and optical parameters. A reference aerial image can, for example, be an acquired aerial image using some kind of aerial image acquisition system, or a simulated aerial image, e.g., a target aerial image that indicates the desired outcome of the aerial image generation method. Mask parameters describe properties of the photolithography mask, e.g., a bias concerning the size of the structures on the photolithography mask with respect to their size in the model or design, corner rounding, side wall angle, layer heights, refractive indices, etc.

Optical parameters describe properties of the optics of the system used to obtain the reference aerial images, e.g., illumination setting (NA, pupil geometry, intensity distribution, coherence, etc.), imaging setting (NA, pupil geometry, obscurations, aberrations, apodisation, defocus, distortion, magnification, etc.), sensor model (intensity integration over active sensor area, pixel size, dark current, shot noise, stray light, etc.), motion blur due to scanning, field-dependent effects (aberrations in both illumination and imaging, etc.), etc. By adjusting at least one parameter of the method based on reference aerial images the accuracy of the generated aerial image is improved. This calibration step furthermore allows for various applications that require highly accurate simulations of aerial images that are comparable to acquired aerial images, e.g., in defect detection in a die-to-database method.

In a preferred embodiment (that can be combined with the previous preferred embodiment), the method for generating an aerial image of a model of a photolithography mask further comprises registering one or more reference aerial images of the photolithography mask to corresponding generated aerial images of the model of the photolithography mask, and reporting at least one registration parameter. Registration parameters contain any (isomorphic) transformation to align a reference aerial image to a generated aerial image, e.g., translations, shifts, rotations, scalings, shears, non-linear transformations, etc. This allows for an accurate comparison of reference aerial images and simulated aerial images for various applications, e.g., for defect detection in a die-to-database method.

According to an aspect of the preferred embodiments, the one or more reference aerial images comprise a focus stack of a photolithography mask. In this way, calibration and registration parameters can be found that accommodate different defocus values.

A computer implemented method for improving a model, e.g., a design pattern, of a photolithography mask, for repairing a photolithography mask, for determining the quality of a photolithography mask, for taking measurements of a photolithography mask, for detecting or assessing defects in a photolithography mask, or for selecting an illumination setting in a photolithography system according to an embodiment comprises: generating an aerial image of a model of the photolithography mask using a method according to any of the embodiments, examples or aspects described above; analyzing the generated aerial image accordingly; improving the design of the photolithography mask, repairing the photolithography mask, determining the quality of the photolithography mask, detecting or assessing defects in the photolithography mask, or selecting an illumination setting in a photolithography system, using the analysis results.

According to an embodiment, a computer implemented method for training a machine learning model that maps a model of a photolithography mask to an aerial image of the photolithography mask, comprises: generating aerial images of models of multiple photolithography masks using a method of any one of the embodiments, examples or aspects described above; and training the machine learning model using training data comprising the generated aerial images. In this way, a particularly fast and efficient training of the machine learning model can be accomplished, since large parts of the training data can be obtained by use of simulation instead of time-consuming acquisition.

According to an embodiment, a computer implemented method for training a machine learning model for defect detection in an acquired aerial image of a photolithography mask comprises: generating model pairs for multiple photolithography masks, each model pair containing a defect-free model of a photolithography mask, i.e., a model without defect, and a defective model of the same photolithography mask, i.e., a model including one or more defects; generating aerial image pairs from the model pairs by applying a method of any one of the embodiments, examples or aspects described above to the defect-free model and to the defective model of each model pair; and training the machine learning model using training data comprising the aerial image pairs.

A computer-readable medium according to an embodiment of the invention has stored thereon a computer program executable by a computing device, the computer program comprising code for executing a method for generating an aerial image of a photolithography mask according to an embodiment, example or aspect described above.

A computer program product according to an embodiment of the invention comprises instructions which, when the program is executed by a computer, cause the computer to carry out a method for generating an aerial image of a photolithography mask according to an embodiment, example or aspect described above.

A system for generating an aerial image of a model of a photolithography mask according to an embodiment of the invention comprises a data analysis device comprising at least one memory and at least one processor configured to perform the steps of a computer implemented method for generating an aerial image of a photolithography mask according to an embodiment, example or aspect described above.

A system for improving a model of a photolithography mask, for repairing a photolithography mask, for determining the quality of a photolithography mask, for taking measurements of a photolithography mask, for detecting or assessing defects in a photolithography mask, or for selecting an illumination setting for a photolithography system according to an embodiment of the invention comprises a data analysis device comprising at least one memory and at least one processor configured to perform the steps of a computer implemented method for generating an aerial image of a photolithography mask according to an embodiment, example or aspect described above. The system can, optionally, also contain a subsystem for obtaining an aerial image of the photolithography mask that can be used in the analysis of the generated aerial image of the photolithography mask, e.g., for comparison.

A system for detecting defects in a photolithography mask according to an embodiment of the invention comprises: a subsystem for obtaining an aerial image of the photolithography mask, a data analysis device comprising at least one memory and at least one processor configured to perform the steps of a computer implemented method for generating an aerial image of a photolithography mask according to an embodiment, example or aspect described above.

A system for assessing the relevance of defects in a photolithography mask according to an embodiment of the invention comprises: a subsystem for obtaining a charged particle beam image of the photolithography mask, a data analysis device comprising at least one memory and at least one processor configured to perform the steps of a computer implemented method for assessing the relevance of defects in a photolithography mask.

The invention described by examples and embodiments is not limited to the embodiments and examples but can be implemented by those skilled in the art by various combinations or modifications thereof.

### BRIEF DESCRIPTION OF DRAWINGS

FIG. 1 illustrates an exemplary transmission-based photolithography system, e.g., a deep ultraviolet (DUV) photolithography system;

FIG. 2 illustrates the propagation of incoming electromagnetic waves through a transmission-based photolithography mask;

FIG. 3 illustrates an exemplary reflection-based photolithography system, e.g., an extreme ultra-violet light (EUV) photolithography system;

FIG. 4 illustrates the propagation of incoming electromagnetic waves through a reflection-based photolithography mask;

FIG. 5A shows the amplitude of a simulated electromagnetic near field of a photolithography mask generated using the rigorous coupled-wave analysis (RCWA) method;

FIG. 5B shows the amplitude of a simulated electromagnetic near field of the same photolithography mask using the thin element approximation (TEA) method;

FIG. 6 shows a flowchart of a computer implemented method according to an embodiment of the invention;

FIG. 7 shows a flowchart of a computer implemented method for generating an aerial image of a model of a photolithography mask according to an example for transmission-based photolithography masks;

FIG. 8 shows a flowchart of a computer implemented method for generating an aerial image of a model of a photolithography mask according to another example for reflection-based photolithography masks;

FIG. 9 shows a flowchart of a computer implemented method for generating an aerial image of a model of a photolithography mask according to an example;

FIGS. 10A and 10B illustrate the effect of the sampling grid resolution during sampling of characteristic functions on the approximation error;

FIG. 11 shows a comparison of the convergence rate of the wave propagation method implemented using discretized binary characteristic functions or discretized band-limited characteristic functions;

FIG. 12 illustrates the dependency of the phase shift vector α on the angle ϕ of the incoming electromagnetic waves;

FIGS. 13A-13D illustrate the steps of a computer implemented method for generating an aerial image of a model of a photolithography mask according to an embodiment of the invention;

FIGS. 14A-14C show a comparison of aerial images of a model of a photolithography mask obtained by three different simulation methods;

FIG. 15 illustrates the use of a calibration step within a defect detection method for detecting defects in an aerial image of a photolithography mask;

FIG. 16 illustrates the calibration step in FIG. 15 including an optimization of mask and/or optical parameters;

FIG. 17 illustrates the effect of the calibration step in FIG. 15;

FIG. 18 illustrates the calibration step in FIG. 15 including a registration;

FIG. 19 illustrates the calibration step in FIG. 15 including a combination of a prior mask and/or optical parameter optimization followed by a registration;

FIG. 20 illustrates the calibration step in FIG. 15 including a joint mask and/or optical parameter optimization and registration;

FIG. 21 illustrates a training method for a machine learning model for generating an aerial image of a model of a photolithography mask;

FIG. 22 shows sample models that are used as training data to train the machine learning model in FIG. 21;

FIG. 23 illustrates a training method for a machine learning model for defect detection in photolithography masks;

FIG. 24 illustrates the generation of training data for training the machine learning model for defect detection in FIG. 23;

FIG. 25 illustrates a method for improving a model of a photolithography mask, for repairing a photolithography mask, for determining the quality of a photolithography mask, for taking measurements of a photolithography mask, for detecting or assessing defects in a photolithography mask, or for selecting an illumination setting in a photolithography system;

FIG. 26 illustrates a computer implemented method for detecting defects in a photolithography mask according to an embodiment of the invention;

FIG. 27 illustrates a computer implemented method for assessing the relevance of defects in a photolithography mask according to an embodiment of the invention;

FIG. 28 illustrates a system for generating an aerial image of a model of a photolithography mask according to an embodiment of the invention;

FIG. 29 illustrates a system for detecting defects in a photolithography mask according to an embodiment of the invention; and

FIG. 30 illustrates a system for assessing the relevance of defects in a photolithography mask according to an embodiment of the invention.

### DETAILED DESCRIPTION

In the following, advantageous exemplary embodiments of the invention are described and schematically shown in the figures. Throughout the figures and the description, same reference numbers are used to describe same features or components.

The methods and systems herein can be used with a variety of photolithography systems, e.g., transmission-based photolithography systems 10 or reflection-based photolithography systems 10′.

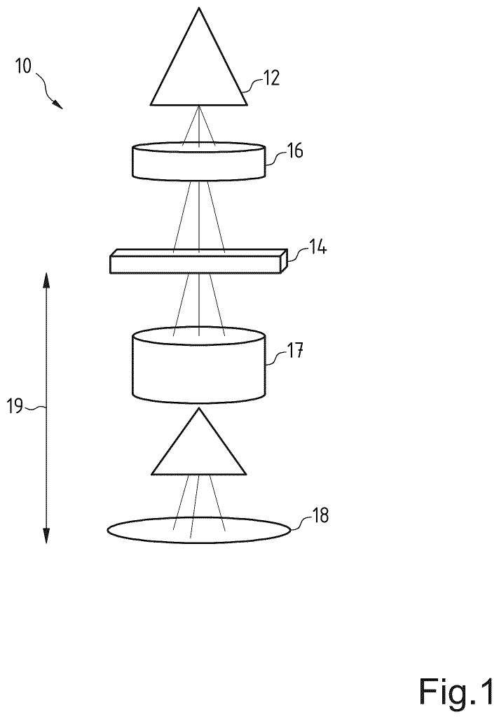

FIG. 1 illustrates an exemplary transmission-based photolithography system 10, e.g., a DUV photolithography system. Major components are a radiation source 12, which may be a deep-ultraviolet (DUV) excimer laser source, imaging optics which, for example, define the partial coherence and which may include optics that shape radiation from the radiation source 12, a photolithography mask 14, illumination optics 16 that illuminate the photolithography mask 14 and projection optics 17 that project an image of the photolithography mask model 92, e.g., the design pattern, onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin (Gmax), wherein n is the refractive index of the media between the substrate and the last element of the projection optics 17, and Gmax is the largest angle of the beam exiting from the projection optics 17 that can still impinge on the wafer plane 18.

In the present document, the terms “radiation” or “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 3-100 nm).

Illumination optics 16 may include optical components for shaping, adjusting and/or projecting radiation from the radiation source 12 before the radiation passes the photolithography mask 14. Projection optics 17 may include optical components for shaping, adjusting and/or projecting the radiation after the radiation passes the photolithography mask 14. The illumination optics 16 exclude the light source 12, the projection optics exclude the photolithography mask 14.

Illumination optics 16 and projection optics 17 may comprise various types of optical systems, including refractive optics, reflective optics, apertures and catadioptric optics, for example. Illumination optics 16 and projection optics 17 may also include components operating according to any of these design types for directing, shaping or controlling the projection beam of radiation, collectively or singularly.

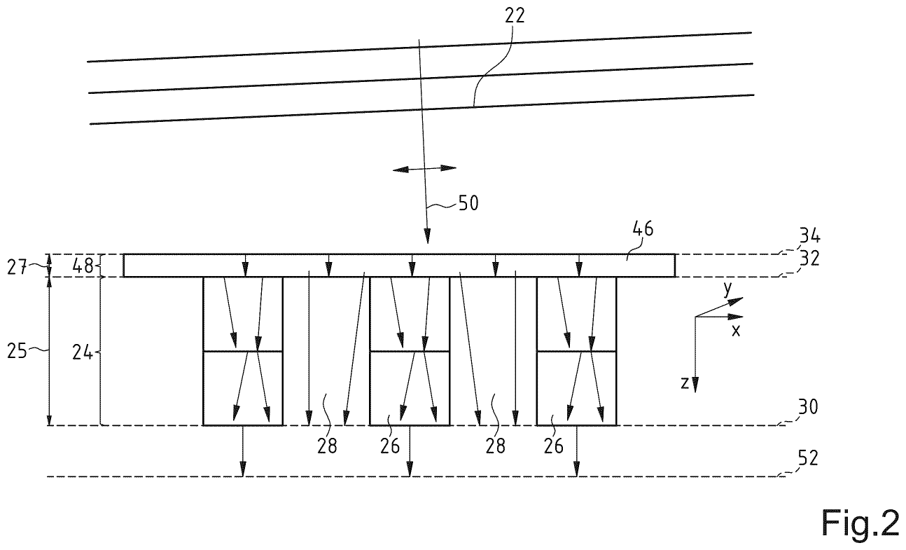

According to an example illustrated in FIG. 2, the simulated electromagnetic waves are incident on the base plane 34, propagated within the second section 27 of the photolithography mask 14 from the base plane 34 to the boundary plane 32, and within the first section 25 of the photolithography mask 14 from the boundary plane 32 to the structure plane 30. In this way, the computer implemented method for generating an aerial image 64 can be applied to transmission-based photolithography masks, e.g., DUV photolithography masks.

FIG. 2 illustrates the propagation of incoming electromagnetic waves 22 through a transmission-based photolithography mask 14, e.g., a DUV photolithography mask. The photolithography mask 14 comprises a first section 25 and a second section 27. The first section 25 contains a grating 24, and the second section 27 contains a mask carrier 48. The grating 24 is formed by a combination of absorber structures 26 and non-absorber structures 28. The absorber structures 26 are made of one or more materials which absorb electromagnetic waves 22, e.g., titanium nitride or tantalum nitride, etc. The non-absorber structures 28 are made of one or more materials which absorb electromagnetic waves 22 to a lower degree than the absorber material. For example, the non-absorber structures 28 can comprise vacuum. Thus, the grating 24 is an inhomogeneous medium. The absorber structures 26 and the non-absorber structures 28 are deposited on a mask carrier 48. The mask carrier 48 can comprise a substrate layer 46. The mask carrier 48 in the photolithography mask 14 is delimited by a boundary plane 32 and a base plane 34 which is preferably parallel to the boundary plane 32. The boundary plane 32 is a surface plane of the mask carrier 48. The base plane 34 is a boundary plane through which the electromagnetic waves 22 enter the grating 24. The incoming electromagnetic wave 22 impinge on the base plane 34. The base plane 34 is forming an interface between the mask carrier 48 and the outside of the photolithography mask 14 through which the electromagnetic waves 22 propagate. The absorber structures 26 in the grating 24 of the photolithography mask 14 are delimited by the boundary plane 32 and a structure plane 30. The structure plane 30 is a boundary plane which contains the portion of the surface of the absorber structures 26, which is facing away from the boundary plane 32. Preferably, the structure plane 30 is parallel to the boundary plane 32. The first section 25 of the photolithography mask 14 extends between the structure plane 30 and the boundary plane 32 and is delimited by these planes. The second section 27 of the photolithography mask 14 extends between the boundary plane 32 and the base plane 34 and is delimited by the boundary plane 32 and the base plane 34.

For transmission-based photolithography masks 14, according to an example, the simulated electromagnetic waves 22 are incident on the base plane 34, propagated within the second section 27 of the photolithography mask 14 from the base plane 34 to the boundary plane 32, and within the first section 25 of the photolithography mask 14 from the boundary plane 32 to the structure plane 30.

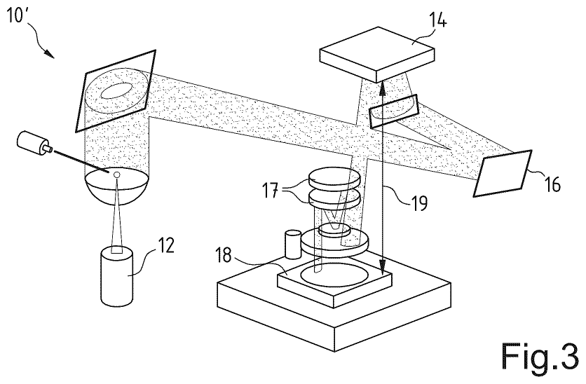

FIG. 3 illustrates an exemplary reflection-based photolithography system 10′, e.g., an extreme ultraviolet light (EUV) lithography system. Major components are a radiation source 12, which may be a laser plasma light source, illumination optics 16 which, for example, define the partial coherence and which may include optics that shape radiation from the radiation source 12, a photolithography mask 14, and projection optics 17 that project an image of the photolithography mask model 92, the design pattern, onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin (Gmax), wherein n is the refractive index of the media between the substrate and the last element of the projection optics 17, and Gmax is the largest angle of the beam exiting from the projection optics 17 that can still impinge on the wafer plane 18.

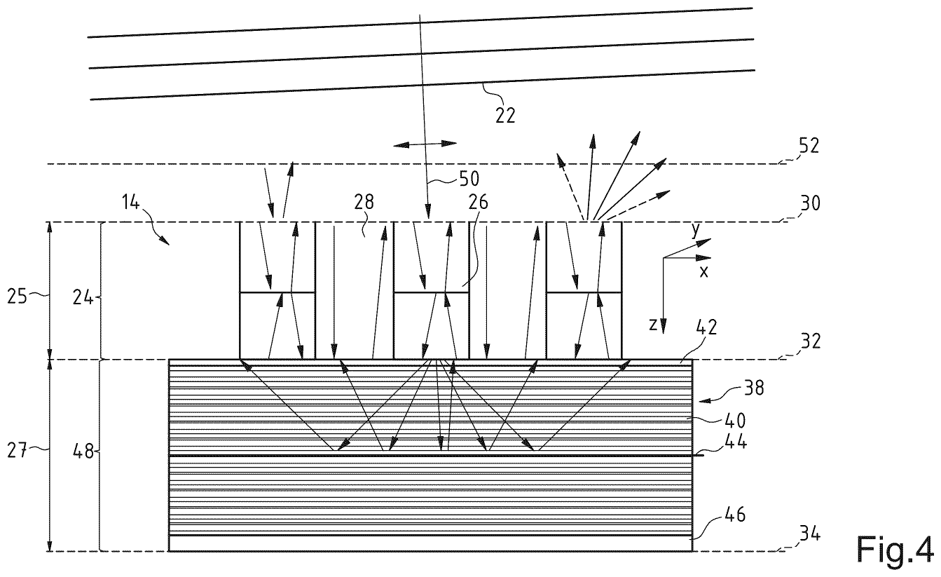

According to an example illustrated in FIG. 4, the mask carrier 48 comprises a multilayer 38 in the form of a stack of optical thin films for reflecting the electromagnetic waves, and the simulated electromagnetic waves are incident on the structure plane 30, propagated within the first section 25 of the photolithography mask 14 from the structure plane 30 to the boundary plane 32, reflected within the multilayer 38 in the second section 27 of the photolithography mask 14 and propagated within the first section 25 of the photolithography mask 14 from the boundary plane 32 to the structure plane 30. In this way, the computer implemented method for generating an aerial image 64 can be applied to reflection-based photolithography masks, e.g., EUV photolithography masks.

FIG. 4 illustrates the propagation of incoming electromagnetic waves 22 through a reflection-based photolithography mask 14, e.g., an EUV photolithography mask. The photolithography mask 14 comprises a first section 25 and a second section 27. The first section 25 contains a grating 24, and the second section 27 contains a mask carrier 48. The grating 24 contains absorber structures 26 and non-absorber structures 28 forming a model 92 of at least a portion of the mask carrier 48 to be printed onto a wafer. The absorber structures 26 are made of one or more materials which absorb electromagnetic waves 22, e.g., titanium nitride or tantalum nitride, etc. The non-absorber structures 28 are made of one or more materials which absorb electromagnetic waves 22 to a lower degree than the absorber material. For example, the non-absorber structures 28 can comprise vacuum or air. Thus, the absorber structures 26 and the non-absorber structures 28 form an inhomogeneous medium. The absorber structures 26 and the non-absorber structures 28 are deposited on a mask carrier 48. The mask carrier 48 comprises a multilayer 38 in the form of a stack of optical thin films 40 for reflecting the electromagnetic waves 22. The mask carrier 48 can comprise a capping layer 42 and/or a substrate layer 46. The reflection of the electromagnetic waves 22 by the stack of optical thin films 40 corresponds to a reflection of the electromagnetic waves 22 at the effective mirror plane 44. The mask carrier 48 in the photolithography mask 14 is delimited by a boundary plane 32 and a base plane 34 which is preferably parallel to the boundary plane 32. The boundary plane 32 is a surface plane of the mask carrier 48. The absorber structures 28 in the grating 24 of the photolithography mask 14 are delimited by the boundary plane 32 and a structure plane 30. The structure plane 30 is a boundary plane which contains the portion of the surface of the absorber structures 26, which is facing away from the boundary plane 32. Preferably, the structure plane 30 is parallel to the boundary plane 32.

The structure plane 30 is a boundary plane through which the electromagnetic waves 22 enter the first section 25, e.g., the grating 24. The incoming electromagnetic waves 22 impinge on the structure plane 30. The structure plane 30 forms an interface between the mask 14 and the outside of the photolithography mask 14 through which the electromagnetic waves 22 propagate. The first section 25 of the photolithography mask 14 extends between the structure plane 30 and the boundary plane 32 and is delimited by these planes. The second section 27 of the photolithography mask 14 extends between the boundary plane 32 and the base plane 34 and is delimited by the boundary plane 32 and the base plane 34.

For reflection-based photolithography masks 14, according to an example, the mask carrier 48 comprises a multilayer 38 in the form of a stack of optical thin films 40 for reflecting the electromagnetic waves 22, and wherein the simulated electromagnetic waves 22 are incident on the structure plane 30, propagated within the first section 25 of the photolithography mask 14 from the structure plane 30 to the boundary plane 32, reflected within the multilayer 38 in the second section 27 of the photolithography mask 14 and propagated within the first section 25 of the photolithography mask 14 from the boundary plane 32 to the structure plane 30.

An electromagnetic near field 20 indicates the distribution of the electromagnetic waves 22 in a near field plane 52. The near field plane can be located next to the structure plane 30 of the photolithography mask. Preferably, the near field plane 52 is parallel to the structure plane 30 or the base plane 34 of the photolithography mask 14. The near field plane 52 can, in general, be located anywhere between the structure plane 30 and the wafer plane 18, for example, at a distance between 0 and 1000 nm from the structure plane 30, preferably at a distance between 0 and 100 nm, more preferably at a distance between 0 and 50 nm, even more preferably at a distance between 0 and 20 nm and most preferably at a distance between 0 and 10 nm. In a preferred embodiment of the invention the near field plane 52 and the structure plane 30 are identical.

Known methods for simulating electromagnetic near fields 20 or aerial images 64 often either require too much computation time or are not sufficiently accurate.

For simulating the interaction of electromagnetic waves 22 with a photolithography mask 14 the propagation of the electromagnetic waves 22 within the different layers of the photolithography mask 14 comprising different materials with different refractive indices has to be taken into account.

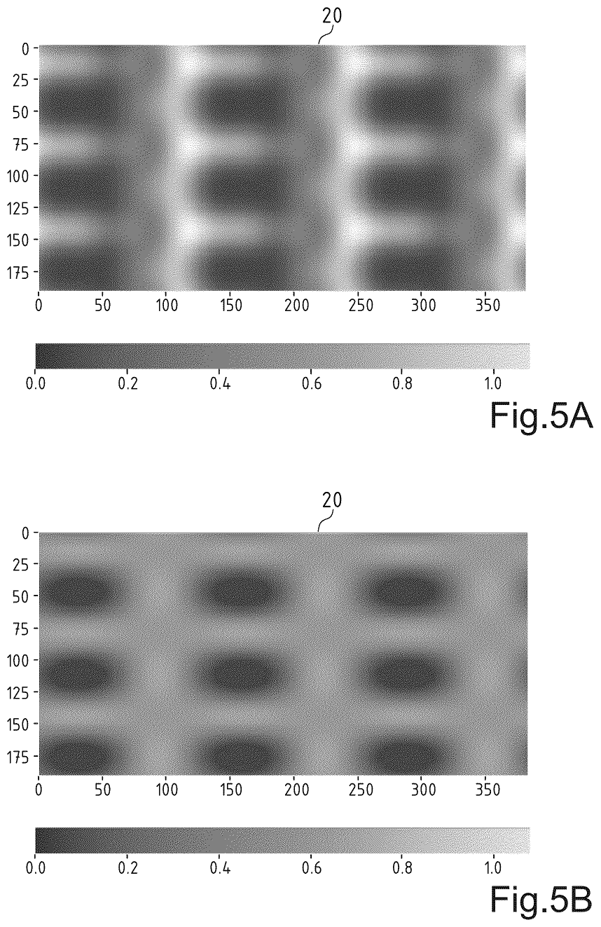

For simulating electromagnetic near fields 20 or aerial images 64, rigorous simulation techniques such as finite difference time domain (FDTD), the finite-element method (FEM) or the rigorous coupled wave analysis (RCWA) method are often used. For example, FIG. 5A shows the amplitude of a simulated electromagnetic near field 20 of a photolithography mask 14 using the rigorous coupled-wave analysis (RCWA) method. However, these methods are computationally extremely expensive, which makes these techniques not feasible for full-chip applications. A full mask simulation can require multiple years.

FIG. 5B shows the amplitude of a simulated electromagnetic near field 20 of the same photolithography mask 14 as in FIG. 5A using the thin element approximation (TEA) method. The thin element approximation method is an efficient method to analyze diffractive optical elements. The TEA method assumes that the thickness of the structures on the photolithography mask 14 is very small compared to the wavelength of the incoming light and that the widths of the structures on the photolithography mask 14 are very large compared to the wavelength. However, as photolithographic processes use radiation of shorter and shorter wavelengths, and the structures on the photolithography mask 14 become smaller and smaller, the assumptions of the TEA method can break down. In this case the photolithography mask 14 cannot be approximated by a flat surface photolithography mask anymore. Instead, the interaction of the radiation at a wavelength below the height of the structures on the photolithography mask 14 leading to the so-called mask 3D effects must be taken into account. Therefore, a method for generating an aerial image 64 of the photolithography mask 14 is required, which is fast and accurate even for short wavelengths.

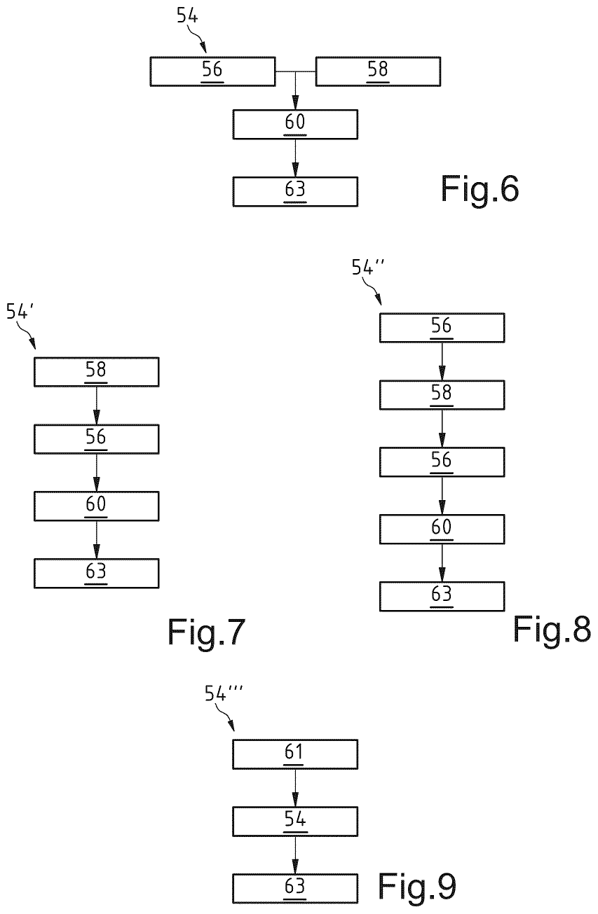

To meet these goals, a computer implemented method for generating an aerial image of a model of a photolithography mask according to an embodiment of the invention is described with respect to FIG. 6.

The computer implemented method 54 for generating an aerial image of a model of a photolithography mask under illumination by incident electromagnetic waves according to an embodiment comprises: a) approximately simulating the propagation of the incident electromagnetic waves within a first section of the photolithography mask that comprises multiple structures in a first section simulation step 56; b) simulating the propagation of the simulated electromagnetic waves from step a) within a second section of the photolithography mask analytically or numerically in a second section simulation step 58; c) simulating a representation of an electromagnetic near field within the model of the photolithography mask by propagating the simulated electromagnetic waves from step b) to a near field plane in a near field generation step 60; and d) generating an aerial image of the photolithography mask by applying a simulation of an imaging process of a photolithography system or metrology system to the representation of the electromagnetic near field in an aerial image generation step 63.

According to an embodiment, the photolithography mask 14 comprises a mask carrier 48 and a grating 24, the grating 24 comprises absorber structures 26 and non-absorber structures 28 forming a model 92 or design pattern on at least a portion of the mask carrier 48. The photolithography mask 14 comprises a first section 25 extending between a structure plane 30 and a boundary plane 32 of the photolithography mask 14 and a second section 27 extending between the boundary plane 32 and a base plane 34 of the photolithography mask 14. The first section 25 comprises the grating 24, and the second section 27 comprises the mask carrier 48.

According to an example, simulating the imaging process comprises resampling of the simulated electromagnetic near field 20. Thus, the resolution of the simulated aerial image 64 can be increased without notably increasing the computation time. In this way, aerial images 64 of a resolution comparable to those obtained by rigorous simulation methods can be obtained.

The computer implemented method 54 according to the embodiment can be applied to transmission-based photolithography masks 14 and reflection-based photolithography masks 14.

FIG. 7 shows a flowchart of a computer implemented method 54′ for generating an aerial image 64 of a model of a photolithography mask 14 in case of a transmission-based photolithography mask 14 as shown in FIG. 2. In the computer implemented method 54′ the simulated electromagnetic waves 22 are incident on the photolithography mask, e.g., on the base plane 34, propagated within the second section 27 of the photolithography mask, e.g., from the base plane 34 to the boundary plane 32, in a second section simulation step 58, and within the first section 25 of the photolithography mask 14, e.g., from the boundary plane 32 to the structure plane 30, in a first section simulation step 56. Then a representation of the electromagnetic near field 20 of the model of the photolithography mask 14 in a near field plane 52 is obtained in a near field generation step 60. Finally, an aerial image 64 is generated from the representation of the near field 20 by applying a simulation of an imaging process of a photolithography system or metrology system to the representation of the electromagnetic near field in an aerial image generation step 63.

FIG. 8 shows a flowchart of a computer implemented method 54″ for generating an aerial image 64 of a model of a photolithography mask 14 in case of a reflection-based photolithography mask 14 as shown in FIG. 4. In the computer implemented method 54″ the mask carrier 48 comprises a multilayer 38 in the form of a stack of optical thin films 40 for reflecting the electromagnetic waves 22, and the simulated electromagnetic waves 22 are incident on the photolithography mask, e.g., on the structure plane 30, propagated within the first section 25 of the photolithography mask 14, e.g., from the structure plane 30 to the boundary plane 32, in a first section simulation step 56, reflected within the multilayer 38 in the second section 27 of the photolithography mask 14 in a second section simulation step 58 and propagated within the first section 25 of the photolithography mask 14, e.g., from the boundary plane 32 to the structure plane 30, in a second first section simulation step 56. Then a representation of the electromagnetic near field 20 of the model of the photolithography mask 14 in a near field plane 52 is obtained in a near field generation step 60. Finally, an aerial image 64 is generated from the representation of the near field 20 by applying a simulation of an imaging process of a photolithography system or metrology system to the representation of the electromagnetic near field in an aerial image generation step 63.

Instead of solving the Maxwell equations directly in the first section 25, different approximations can be used to reduce the computation time of the method. According to an example, the propagation of the incident electromagnetic waves within the first section 25 of the photolithography mask 14 in step a) is approximately simulated using a Helmholtz equation, in particular a forward Helmholtz equation.

In the photolithography setting, the following assumptions can be made: 1) the refractive index is similar for the different materials of the photolithography mask 14, e.g., the refractive index of the structures 26, in particular the absorber structures, is close to the refractive index outside the structures 26, in particular the non-absorber structures, e.g., vacuum. 2) The refractive index distribution in the first section 25 is piecewise constant without requiring a transition to be modeled. 3) The main propagation direction 50 of the incoming electromagnetic waves 22 is near vertical with respect to a main surface of the photolithography mask, in particular to the base plane 34. These assumptions allow for a simplified approximation of the propagation of the electromagnetic waves 22 within the first section 25.

Based on the Maxwell equations, the following equation can be derived for the electric field E of an electromagnetic wave 22:

$$△ E ( r , ω ) + \frac{{ω}^{2}}{{c}^{2}} ε ( r , ω ) E ( r , ω ) = - ∇ \cdot ( \frac{∇ ϵ ( r , ω )}{ϵ ( r , ω )} \cdot E ( r , ω ) ) , \qquad ( 1 )$$

where ω is the angular frequency, c the speed of light and ∈(r,ω) the dielectric function characterizing the specific material. These relations are connected to the refractive index n(r, ω) of a material via ∈(r, ω)=n(r, ω)². The right-hand side couples the electric field components, which makes it hard to find solutions to this equation. Therefore, the right-hand side is preferably neglected. The neglection of the right-hand side remains valid if the following two assumptions are fulfilled: the considered optical system does not show a distinctive response depending upon the incident polarization, and there is no cross coupling between individual polarization components. For the lithography setting at short wavelengths, e.g., for DUV or EUV photolithography masks, there are two reasons for neglecting polarization and phononic effects, so these assumptions are valid. Firstly, the contrasts in the refractive index are low with respect to the different materials within the structures 26 and outside the structures in the first section 25. Secondly, the height a of the structures 26 is larger than the wavelength λ, I.e.,

$$\frac{a}{λ} \geq 2 .$$

Therefore, the right-hand side of equation (1) can be neglected resulting in a Helmholtz equation

$$△ E ( r , ω ) + \frac{{ω}^{2}}{{c}^{2}} ϵ ( r , ω ) E ( r , ω ) = 0$$

The Helmholtz equation can be simplified further. Using the following relations concerning the magnitude of the wave number |k|

$$\vert k \vert = \sqrt{{k}_{x}^{2} + {k}_{y}^{2} + {k}_{z}^{2}} = \frac{ω}{c} n ( r , ω )$$

and its connection to the wavelength λ

$$\vert k \vert = {k}_{0} n ( r , ω ) = \frac{2 π}{{λ}_{0}} n ( r , ω ) ,$$

where k₀ and λ₀ are respectively the wave vector and wavelength in vacuum, the Helmholtz equation can be rewritten as

$$△ E ( r , ω ) + {k}_{o}^{2} {n}^{2} ( r , ω ) E ( r , ω ) = 0 .$$

This equation can be rewritten using the transverse Helmholtz operator as follows:

$$( {δ}_{z}^{2} + {ℋ}_{𝒯} ) {E}_{x , y} = 0 ,$$

$$where$$

$${ℋ}_{𝒯} = {δ}_{x}^{2} + {δ}_{y}^{2} + {k}_{0}^{2} {n}^{2} ( x , y , z ) .$$

This equation can be rewritten as

$$( i \sqrt{{ℋ}_{𝒯}} + {δ}_{z} ) ( i \sqrt{{ℋ}_{𝒯}} - {δ}_{z} ) {E}_{x , y} = 0 .$$

Here, the square root Helmholtz operator is introduced, being formally defined in terms of a power-series. Moreover, it is assumed that the commutator δz [symbol] can be neglected, which physically implies that back reflections within the inhomogeneous medium are ignored. Then, the forward Helmholtz equation is identified as

$${δ}_{z} {E}_{x , y} = i \sqrt{{ℋ}_{𝒯}} {E}_{x , y} .$$

The ordinary partial differential equation can be solved using multiplication with an integrating factor:

$${E}_{x , y} ( x , y , {z}_{0} + z ) = {exp}^{iz \sqrt{{ℋ}_{𝒯}}} {E}_{x , y} ( x , y , {z}_{0} ) .$$

The exponential operator can be approximated by an integral operator as shown in the appendix A of the PhD thesis “Efficient wave-optical simulations for the modeling of micro-optical elements” by Soeren Schmidt at the University of Jena. Reference is hereby made in full to the aforementioned PHD thesis, and its disclosure content is included in the description of this invention. The approximation by the integral operator yields:

$$E ( x , y , {z}_{0} + Δ z ) = \frac{1}{2 π} \int \tilde{E} ( {k}_{x} , {k}_{y} , {z}_{0} ) {e}^{{ik}_{z} ( {k}_{x} , {k}_{y} , x , y ) Δ z} {e}^{i ( {k}_{x} x + {k}_{y} y )} {dk}_{x} {dk}_{y} ,$$

$$\begin{matrix}\tilde{E} ( {k}_{x} , {k}_{y} , {z}_{0} ) = \frac{1}{2 π} \int E ( x , y , {z}_{0} ) {e}^{- i ( {k}_{x} x + {k}_{y} y )} dx dy \\ = ℱ \{ E ( x , y , {z}_{0} ) \}\end{matrix}$$

$${k}_{z} = \sqrt{{k}_{0}^{2} {n}^{2} - {k}_{x}^{2} - {k}_{y}^{2} .}$$

This approach is referred to as the angular spectrum of plane wave decomposition (ASPW) as shown in equation 1.8 of the aforementioned PhD thesis. It assumes that the electromagnetic waves are propagated within a homogeneous medium with refractive index n. However, this does not hold for the first section 25 of the photolithography mask 14 comprising structures 26 and non-structures.

Therefore, an extension of the ASPW to inhomogeneous media is required to describe the propagation of electromagnetic waves 22 within the first section 25 of the photolithography mask 14.

In order to account for inhomogeneous media, the propagation constant in a subsequent plane z to a given plane z₀ is computed according to the refractive index distribution as described in section 1.4 of the aforementioned PHD thesis

$${k}_{z} ( x , y , {k}_{x} , {k}_{y} ) = \sqrt{{k}_{0}^{2} {n ( x , y , {z}_{0} )}^{2} - {k}_{x}^{2} - {k}_{y}^{2} .}$$

Therefore, according to an example, the forward Helmholtz equation can be solved using a wave propagation method. The wave propagation method is a generalization of the ASPW to inhomogeneous media and describes a wave propagation step in a plane z₀ along the z-direction perpendicular to the base plane by

$$E ( x , y , {z}_{0} + Δ z ) = \frac{1}{2 π} \int ℱ \{ E ( x , y , {z}_{0} ) \} {e}^{{ik}_{z} ( x , y , {k}_{x} , {k}_{y} ) Δ z} {e}^{i ( {k}_{x} x + {k}_{y} y )} {dk}_{x} {dk}_{y} , \qquad ( 2 )$$

where E denotes the electric field component of the electromagnetic field and (kₓ, k_{y}, k_{z})^{T} the wave vector, which locally obeys the dispersion relation

$${k}_{z} ( x , y , {k}_{x} , {k}_{y} ) = \sqrt{{k}_{0}^{2} {n ( x , y , {z}_{0} )}^{2} - {k}_{x}^{2} - {k}_{y}^{2} ,} \qquad ( 3 )$$

where

$${k}_{0} = \frac{2 π}{{λ}_{0}}$$

denotes the wavenumber of light with a wavelength λ₀ in vacuum, n(x, y, z) the refractive index distribution and [symbol] the spatial Fourier Transform. The magnitude of the wave vector k is inversely proportional to the wavelength λ, and the direction of the wave vector is perpendicular to the wave front. By using this wave propagation method, the propagation of the electromagnetic waves within an inhomogeneous medium can be modeled leading to an accurate approximation of the propagation of the electromagnetic waves within the first section of the photolithography mask.

In an embodiment, the first section 25 of the photolithography mask 14 comprises structures 26 and non-structures 28 forming an inhomogeneous medium, e.g., the grating 24 comprises absorber structures and non-absorber structures. The simulation of the propagation of the electromagnetic waves 22 within the first section 25 takes into account this inhomogeneity of the material within the first section 25. At the same time, several simplifying assumptions can be exploited in the photolithography setting. In addition, the simulation of the propagation of the electromagnetic waves 22 within the second section 27 is computed analytically or numerically. In this way, an accurate and fast simulation of the propagation of the electromagnetic waves 22 within the photolithography mask 14 is obtained.

Alternatively, the forward Helmholtz equation can be solved using a beam propagation method. The beam propagation method is described, for example, in chapter 1.3 of the above mentioned PhD thesis “Efficient wave-optical simulations for the modeling of micro-optical elements” by Soeren Schmidt.

In an example, the propagation of the incident electromagnetic waves within the first section of the photolithography mask in step a) is approximately simulated using a machine learning model. The machine learning model can, for example, comprise a neural network, e.g., a deep learning model. For example, the machine learning model can comprise a U-Net or a neural network with at least one attention mechanism, e.g., a Transformer machine learning model. The machine learning model can use a model of the photolithography mask, e.g., a design pattern, as input and map the input to an electromagnetic field as output. The machine learning model can be trained using training data obtained, e.g., from simulations described above. By using a machine learning model, the computation time can be strongly reduced, as after training a single and fast forward pass is sufficient to compute the propagation of the incident electromagnetic waves.

Due to the dependence of the dispersion relation in (3) on the spatial variables (x,y) the wave propagation method in (2) cannot be implemented using Fast Fourier Transforms (FFT). In order to use FFTs and reduce the computation time the wave propagation method in (2) can be reformulated using characteristic functions.

In an example, the first section 25 of the photolithography mask 14 is decomposed into different materials by defining a characteristic function for each material that indicates the presence of the material within different locations in the first section 25 of the photolithography mask 14, wherein at least one characteristic function is non-binary.

The first section 25 of the photolithography mask 14 can be decomposed into a finite number M of pairwise disjoint and homogeneous subregions with refractive index nₘ. Then, the refractive index distribution n(x, y, z₀) within a given layer z₀ can be rewritten using characteristic functions. A characteristic function Iₘ^{z}^{₀}:X×Y→ [symbol] for a material m is a mapping from a spatial domain X×Y⊆ [symbol] × [symbol] to a value range [symbol] , which represents the presence of the material m for each location (x,y) of the spatial domain. For example

$${I}_{m}^{{z}_{0}} ( x , y ) = \{ \begin{matrix}1 , & n ( x , y , {z}_{0} ) = {n}_{m} \\ 0 , & n ( x , y , {z}_{0} ) \neq {n}_{m}\end{matrix}$$

indicates a binary characteristic function with a value range [symbol] ={0,1}, where nₘ indicates the refractive index of material m. [symbol] can, for example, be a subset of the real numbers [symbol] ( [symbol] ⊆ [symbol] ) or of the complex numbers [symbol] ( [symbol] ⊆ [symbol] ).

FIG. 9 shows a flowchart of a computer implemented method 54″′ for generating an aerial image 64 of a model of a photolithography mask 14 according to an example, comprising an additional characteristic function step 61.

The additional characteristic function step 61 comprises: identifying a number M of materials of the structures 26 in the first section 25 forming the model 92, e.g., the design pattern, of the photolithography mask 14; defining a characteristic function Iₘ^{z}^{₀}:X×Y→ [symbol] for each material m∈{1, . . . , M} indicating the presence of the material for locations (x,y) of the photolithography mask 14 within a subset X×Y⊆ [symbol] × [symbol] of an x/y-plane at z=z₀, wherein the x/y-plane is orthogonal to the z-direction, which is perpendicular to the base plane 34; simulating the propagation of the electromagnetic waves 22 as a weighted sum over a propagation step within each of the identified materials:

$$E ( x , y , {z}_{0} + Δ z ) = {\sum }_{m = 1}^{M} {I}_{m}^{{z}_{0}} ( x , y ) {- 1}^{} \{ {e}^{i {k}_{z}^{m} ( {k}_{x} , {k}_{y} ) Δ z} \{ E ( x , y , {z}_{0} ) \} \} , \qquad ( 4 )$$

where [symbol] ⁻¹ indicates the inverse Fourier Transform. The use of characteristic functions allows for an FFT based implementation of the wave propagation method in (2), thus saving computation time. The integrator in (4) converges linearly with the step size.

However, the discretization of the commonly used binary characteristic functions is problematic. Since binary characteristic functions are discontinuous, the Shannon-Nyquist theorem requires a very high sampling frequency (at least twice the maximum frequency of the signal) and, thus, a very high resolution of the sampling grid. In particular, if the edges of the structures 26 do not align with the sampling grid, the sampling is inaccurate. In addition, the resolution of the sampling grid depends on the size of the smallest feature. The high resolution of the sampling grid in turn leads to high computation times for generating the aerial image 64.

Therefore, according to an aspect of the example the characteristic functions are band-limited. A band-limited characteristic function is a characteristic function for which a finite frequency ω₀ exists such that

$$( ω ) = 0 for \vert ω \vert > {ω}_{0} .$$

According to the Shannon-Nyquist theorem, on the one hand the required sampling frequency of the discretization of a band-limited characteristic function depends on its maximum frequency. On the other hand, a given sampling frequency of a discretization of a band-limited characteristic function directly implies its maximum frequency.

By using band-limited characteristic functions, the maximum frequency of the characteristic functions can be limited. In this way, according to the Shannon-Nyquist theorem, the required sampling frequency is reduced, so a sampling grid of lower resolution can be used for discretizing the characteristic functions (than in case of binary characteristic functions). In this way, the required computation times for generating the aerial image 64 can be reduced. In addition, the resolution of the sampling grid is independent from the feature size of the features in the model, e.g., the design pattern, of the photolithography mask. In contrast, for binary characteristic functions, the sampling grid resolution depends on the smallest feature of the model of the photolithography mask.

A justification of using discretized band-limited characteristic functions is given in the following: Assuming that the electromagnetic field E only contains energy at long wavelengths in the x/y-plane perpendicular to the base plane 34 of the photolithography mask 14, a linear space invariant low-pass filter P has no effect when applied to the electromagnetic field E, that is:

P(E)≈E

Equivalently, P can be written as a convolution in time domain, and the above implies:

$$\begin{matrix}P ( E ) = \int p ( {t}^{′} ) E ( t - {t}^{′} ) d {t}^{′} \\ \approx \int p ( {t}^{′} ) E ( t ) d {t}^{′} \\ = E ( t ) \int p ( {t}^{′} ) d {t}^{′} \\ = E .\end{matrix}$$

If the filter P is applied to the product of E with a function θ having energy at shorter wavelengths, it follows:

$$\begin{matrix}P ( E \cdot Θ ) = \int p ( {t}^{′} ) E ( t - {t}^{′} ) Θ ( t - {t}^{′} ) d {t}^{′} \\ \approx \int p ( {t}^{′} ) E ( t ) Θ ( t - {t}^{′} ) d {t}^{′} \\ = E ( t ) \int p ( {t}^{′} ) Θ ( t - {t}^{′} ) d {t}^{′} \\ = E \cdot P ( Θ ) .\end{matrix}$$

Thus, if a low pass filter is applied to the product of a slowly varying function E and a fastly varying function θ, then the result is approximately the product of the slowly varying function E and the filtered fastly varying function P(θ).

Applying this result to the propagator of the wave propagation method in (4)

$$P [ E ( {z}_{0} + Δ z ) ] = P ( {\sum }_{m = 1}^{M} {I}_{m}^{{z}_{0}} ( x , y ) O [ E ( {z}_{0} ) ] ) ,$$

where O denotes the linear ASPW propagator

$$O [ E ( {z}_{0} ) ] = {- 1}^{} \{ {e}^{i {k}_{z}^{m} ( {k}_{x} , {k}_{y} ) Δ z} \{ E ( {z}_{0} ) \} \} \qquad ( 5 )$$

and assuming that the electromagnetic field E(z₀) varies on a longer scale than the characteristic functions 120, it follows:

$$P [ E ( {z}_{0} + Δ z ) ] \approx Σ {\sum }_{m = 1}^{M} P ( {I}_{m}^{{z}_{0}} ) O [ E ( {z}_{0} ) ] .$$

Thus, the propagator for the low frequency part of the field E in the wave propagation method in (4) is obtained by applying the filter P to the characteristic functions.

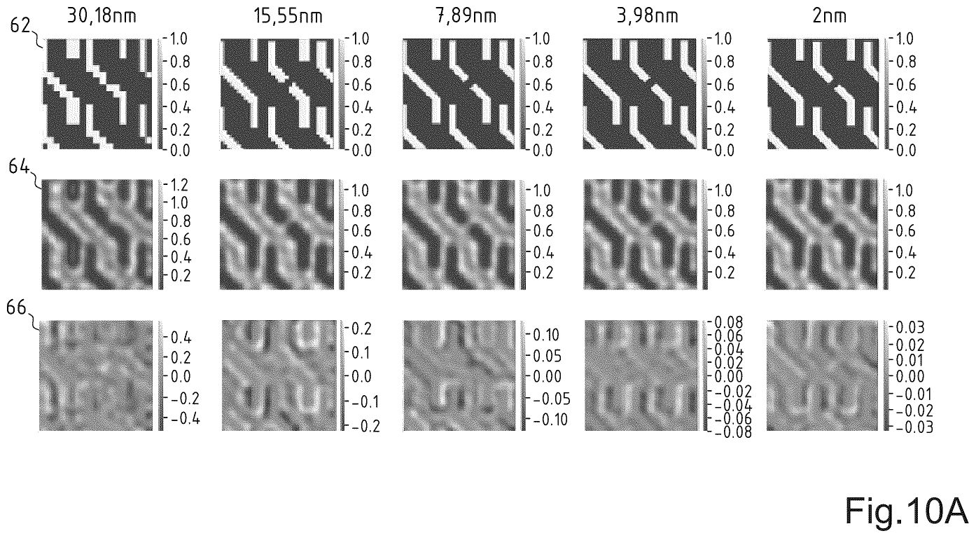

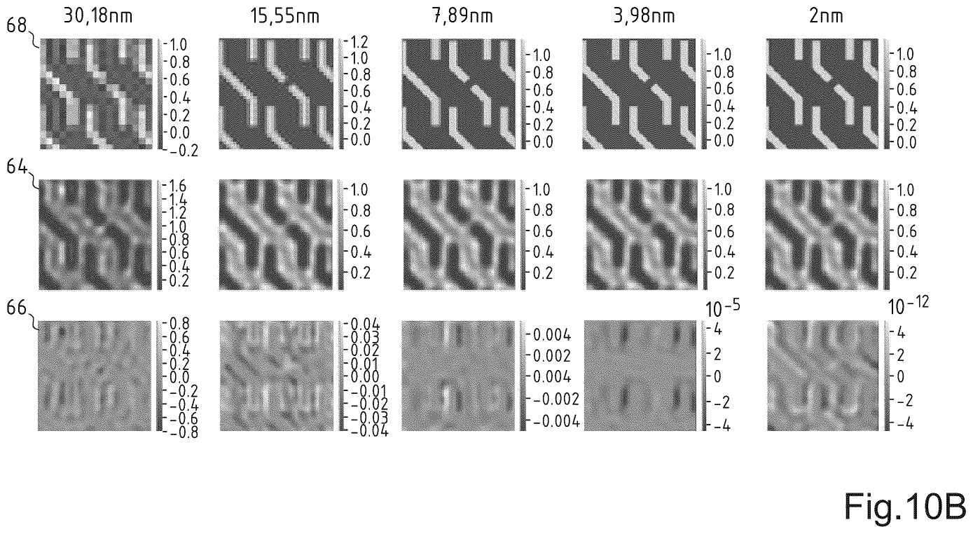

FIG. 10A illustrates the effect of the sampling grid resolution during sampling of binary characteristic functions 62 on the approximation error 66. In each column different sample spacings between 30.18 nm and 2 nm are indicated. In the top row, the sampled binary characteristic functions 62 for a model 92, e.g., a design pattern, of a photolithography mask 14 are shown for the different sample spacings (pixel size in nm). Using the indicated binary characteristic functions 62 an aerial image 64 is generated by a computer implemented method 54″′ for generating an aerial image 64 of a model of a photolithography mask 14 comprising a characteristic function step 61 as described above. In the center row, the generated aerial image 64 corresponding to the respective binary characteristic function 62 in the top row is shown. In the bottom row, the approximation error 66 as the difference between the generated aerial image 64 and a rigorously simulated aerial image 64 for the same underlying model 92, e.g., design pattern, of the photolithography mask 14 is shown. From the results it can be concluded that for binary characteristic functions 62 an approximation error 66 below 1% requires a sample spacing below 2 nm. Thus, for binary characteristic functions 62 a high resolution of the sampling grid is required leading to high computation times.

FIG. 10B illustrates the effect of the sampling grid resolution during sampling of band-limited characteristic functions 68 on the approximation error 66. In each column different sample spacings between 30.18 nm and 2 nm are indicated. In the top row, the sampled band-limited characteristic functions 68 for a model 92, e.g., design pattern, of a photolithography mask 14 are shown for the different sample spacings (pixel size in nm). Using the indicated band-limited characteristic functions 68 an aerial image 64 is generated by a computer implemented method 54″ for generating an aerial image 64 of a model of a photolithography mask 14 comprising a characteristic function step 61 as described above. In the center row, the generated aerial image 64 corresponding to the respective band-limited characteristic function 68 in the top row is shown. In the bottom row, the approximation error 66 as the difference between the generated aerial image 64 and a rigorously simulated aerial image 64 for the same underlying model 92, e.g., design pattern, of the photolithography mask 14 is shown. From the results it can be concluded that for band-limited characteristic functions 68 an approximation error below 1% requires a sample spacing of not even 8 nm. Thus, a coarse resolution is sufficient to obtain accurate aerial images 64 at reduced computation times for band-limited characteristic functions 68.

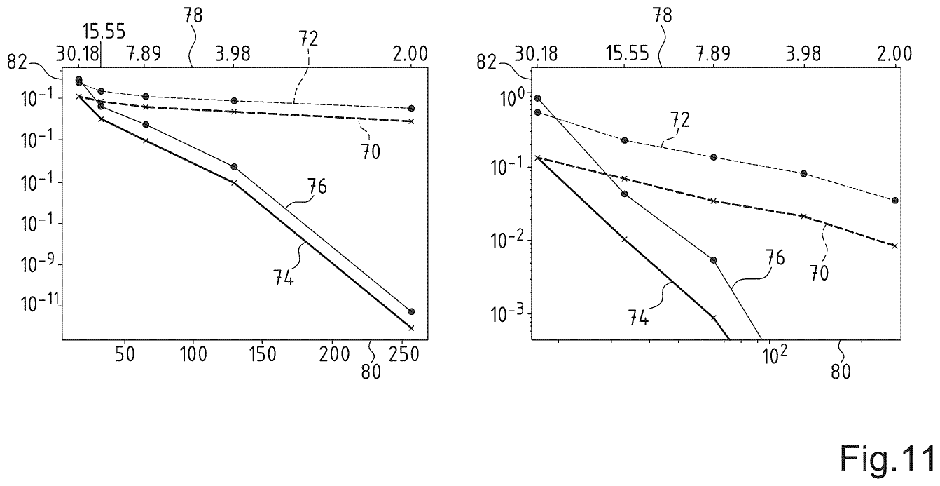

FIG. 11 shows a comparison of the convergence rate of the wave propagation method in equation (4) implemented using discretized binary characteristic functions 62 or discretized band-limited characteristic functions 68. On the top horizontal axis 78 the sample spacing is shown. On the bottom horizontal axis 80 the corresponding number of pixels in one dimension of the sampling grid is shown. On the vertical axis 82 the approximation error 66 is indicated. The plots show the root mean squared error 70 and the maximum error 72 of the binary characteristic functions 62, and the root mean squared error 74 and the maximum error 76 of the band-limited characteristic functions 68. From the plots it can be concluded that the convergence rate of the band-limited characteristic functions 68 is exponential compared to the convergence rate of the binary characteristic functions 62.

By generalizing the concept of characteristic functions to non-binary characteristic functions sub-pixel design features can be resolved, and a speedup factor of about 100 can be achieved.

Apart from band-limited characteristic functions 68, it is also advantageous to use other non-binary characteristic functions to describe the presence of specific materials in different locations (x, y)∈X×Y of the photolithography mask 14 at z=z₀.

For example, it is advantageous to use continuous characteristic functions or complex valued characteristic functions. In this way, the material distribution within the photolithography mask can be described in a more flexible way leading to approximations of higher accuracy.

According to an aspect of the example the value range [symbol] of at least one characteristic function comprises at least one value Iₘ^{z}^{₀}(x, y)∉{0,1}. Thus, at least one characteristic function is not a binary characteristic function, since it maps to at least one non-binary value. In this way, different materials m can be present in the same location (x,y) allowing for a more flexible modeling of the refractive index distribution in the photolithography mask 14, thereby obtaining a more general description of the material distribution in the photolithography mask. By using characteristic functions having overlapping support the accuracy of the wave propagation method can be improved. The support of a real-valued function is the subset of the function domain containing the elements which are not mapped to zero. On the one hand, the presence of different materials in the same location of the photolithography mask can be used to model the distribution of materials in case that different materials are present in the same location. On the other hand, assuming the presence of different materials in the same location can be used as a mathematical means to improve the accuracy of the electromagnetic near field and aerial image even if this material distribution does not correspond to the true material distribution. In this way, more accurate electromagnetic near fields and aerial images can be computed.

According to an aspect of the example the characteristic functions form an affine combination at each location of the photolithography mask at z=z₀:Σₘ₌₁^{M}Iₘ^{z}^{₀}(x, y)=1∀(x, y)∈X×Y. In particular, the characteristic functions can form a convex combination at each location of the photolithography mask at z=z₀. This constraint ensures that the amount of material present in each location of the domain of the characteristic functions is the same and amounts to 1. Thus, an accurate description of the material distribution within the photolithography mask 14 is obtained leading to an accurate approximation of the propagation of the electromagnetic waves 22 within the photolithography mask 14.

According to an aspect of the example, obtaining the characteristic functions comprises decomposing the model 92, e.g., design pattern, of the photolithography mask 14 into elements 94 (e.g., using mathematical functions that describe the contours or aera of the structures 26 such as polygons, Splines, curvilinear elements, etc.), representing the elements 94 by characteristic functions, in particular by binary characteristic functions, and applying a low pass filter to the characteristic functions. The elements 94 can, for example, be represented by characteristic functions taking on a non-zero value, for example 1, inside the element 94 and 0 outside the element 94. For example, each element 94 can be decomposed into one or more triangles, and the triangles can be represented by characteristic functions. The Fourier Transform of polygons can be obtained as described in appendix A of the PhD thesis “Photolithography Simulation by Heinrich Kirchauer at the Technical University of Wien.” Reference is hereby made in full to the aforementioned PhD thesis, and its disclosure content is included in the description of this invention. By applying a low pass filter to the characteristic functions band-limited characteristic functions 68 are obtained. Thus, the wave propagation method in (4) can be simulated using a coarse sampling grid as described above, thereby reducing the computation time.

In particular, applying a low pass filter to the characteristic functions can comprise applying a spatial analytical Fourier Transform to the characteristic functions followed by an inverse Fast Fourier Transform. The analytical Fourier transform can be computed only for the spatial frequencies of the discretized domain of the inverse FFT. This subsampling of the spatial domain limits the maximum frequency of the characteristic functions according to the Shannon-Nyquist theorem. Thus, the discretization corresponds to a low pass filter of the characteristic functions. The result is a representation of the model, e.g., design pattern, of the photolithography mask by use of band-limited characteristic functions, which can be discretized using a sampling grid of a resolution much lower than for binary characteristic functions, thereby reducing the computation time.

According to an example, the analytical Fourier Transform used in the wave propagation method in equation (4) is approximated by a Fast Fourier Transform (FFT). In this way, the computation time is reduced.

The FFT implies periodic boundary conditions. However, due to the arbitrary angle of the incident electromagnetic waves, this assumption does not hold anymore. This inaccuracy is often ignored by approximation methods. Even if the mask model 92, e.g., design pattern, is assumed to be periodic, the arbitrary illumination angle of the incident electromagnetic waves 22, e.g., with respect to the normal 84 of the structure plane 30, implies that the solution of equation (4) is only quasi periodic according to the Floquet Theorem, that means periodic with an additional phase shift α:

$$E ( x + n Δ x ) = E ( x ) {exp}^{i n α} .$$

Therefore, according to an example, the wave propagation method takes into account the angle ϕ of the incident electromagnetic waves 22, e.g., the angle with respect to the normal 84 of the structure plane 30, by assuming quasiperiodic boundary conditions in the propagator step in equation (4) at one or more pairs of opposite boundaries perpendicular to a base plane 34 of the photolithography mask 14, that is in the x/y-plane. By assuming quasiperiodic boundary conditions, the accuracy of the simulated electromagnetic near field is improved.

Let E(x, y, z₀) be quasi-periodic in the x and y coordinates. Then, according to the Floquet theorem, E can be rewritten as a part E′ that is periodic in x and y multiplied with a non-periodic phase shift α=(αₓ, α_{y}) as follows:

$$E ( x , y , {z}_{0} ) = {E}^{′} ( x , y , {z}_{0} ) {exp}^{i ( {α}_{x} x + {α}_{y} y )} .$$

Then the Fourier transform of the periodic part E′ can be written as

$$= \{ {E}^{′} \} = \tilde{E} ( {k}_{x} - {α}_{x} , {k}_{y} - {α}_{y} , {z}_{0} ) .$$

It follows that

$$( {k}_{x} + {α}_{x} , {k}_{y} + {α}_{y} , {z}_{0} ) = \tilde{E} ( {k}_{x} , {k}_{y} , {z}_{0} ) .$$

$$Using$$

$$\tilde{E} ( {k}_{x} , {k}_{y} , {z}_{0} ) = \{ E ( x , y , {z}_{0} ) \} .$$

$$we obtain$$

$$\begin{matrix}E ( x , y , {z}_{0} + Δ z ) = {- 1}^{} \{ {exp}^{i {k}_{z} ( {k}_{x} , {k}_{y} ) Δ z} \tilde{E} ( {k}_{x} , {k}_{y} , {z}_{0} ) \} \\ = {- 1}^{} \{ {exp}^{i {k}_{z} ( {k}_{x} , {k}_{y} ) Δ z} ( {k}_{x} + {α}_{x} , {k}_{y} + {α}_{y} , {z}_{0} ) \} \\ = {- 1}^{} \{ {exp}^{i {k}_{z} ( {k}_{x} - {α}_{x} , {k}_{y} - {α}_{y} ) Δ z} \tilde{E} ( {k}_{x} , {k}_{y} , {z}_{0} ) \} {exp}^{i ( {α}_{x} x + {α}_{y} y )} .\end{matrix}$$

From this it can be concluded that a phase shift a in the input field that is linear in the x and y coordinates can be accommodated by reformulating the dispersion relation in equation (3) as follows:

$${k}_{z} ( x , y , {k}_{x} - {α}_{x} , {k}_{y} - {α}_{y} ) = \sqrt{{k}_{0}^{2} {n ( x , y , {z}_{0} )}^{2} - {( {k}_{x} - {α}_{x} )}^{2} - {( {k}_{y} - {α}_{y} )}^{2}} .$$

Therefore, according to an example, the dispersion relation in (3) can be reformulated using the Floquet theorem. The term within the inverse Fourier Transform is then periodic and can be computed using standard FFT.

In particular, the dispersion relation of the electromagnetic waves 22 within the first section 25 depends on the angle ϕ of the incident electromagnetic waves 22.

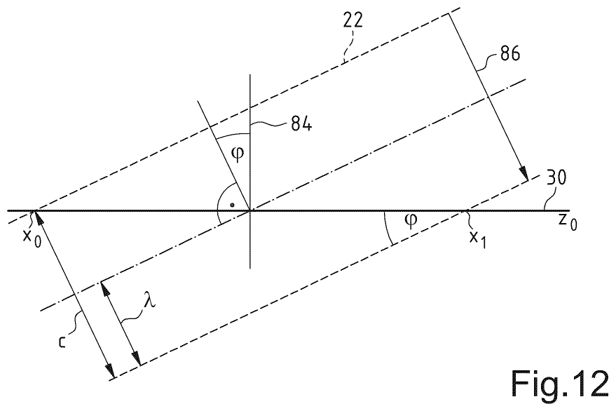

FIG. 12 illustrates the dependency of the phase shift vector α on the angle ϕ of the incoming electromagnetic waves 22. The angle ϕ can be measured with respect to the normal 84 of the structure plane z₀. The electromagnetic waves 22 are propagated in the direction of the wave vector 86. Let x₀ and x₁ indicate the boundaries of the unit cell in the x-direction, that is the smallest non-periodic subset of the periodic model 92, e.g., design pattern. Then, using the relation

$$sin ϕ = \frac{c}{{x}_{1} - {x}_{0}}$$

the phase difference between x₀ and x₁ can be expressed in terms of ϕ as follows:

$${α}_{x} = \frac{c \cdot 2 π}{λ} = \frac{sin ϕ \cdot 2 π ( {x}_{1} - {x}_{0} )}{λ} .$$

The dependence of α_{y} on the angle of the incoming electromagnetic waves 22 can be computed analogously.

For reflection-based photolithography masks 14, simulating the propagation of the simulated electromagnetic waves 22 from step a) within the second section 27 of the photolithography mask 14 analytically or numerically can comprise using an analytical description of the electromagnetic wave propagation within the mask carrier 48 and analytically computing the reflection of the electromagnetic waves 22 at the multilayer 38.

Therefore, according to an example, simulating the reflection of the simulated electromagnetic waves 22 from step a) within the multilayer 38 comprises the analytical computation of reflection coefficients at a boundary, e.g., at the boundary plane 32, between the second section 27 and the first section 25 of the photolithography mask 14, the reflection coefficients describing the propagation of the electromagnetic waves 22 within the stack of optical thin films 40 of the multilayer 38. The propagation within the stack of optical thin films 40 of the multilayer 38 corresponds to a reflection at an effective mirror plane 44 at a specific distance from the boundary plane 32.

In particular, the reflection coefficients at the boundary 32 can be computed separately within the structures 26 and outside the structures 26 in the first section 25 of the photolithography mask 14. For example, the reflection coefficients can be computed separately for each medium of the absorber structures and the non-absorber structures of the grating 24 at the location of the boundary plane 32. In this way, the accuracy of the generated aerial image 64 is improved.

In an example, simulating the propagation of the simulated electromagnetic waves 22 within the second section 27 of the photolithography mask 14 comprises applying the reflection coefficients to the electromagnetic waves 22 incident on the boundary 32.

In particular, simulating the reflection of the electromagnetic waves 22 within the multilayer 38 comprises replacing the phase term e^{ik}^{_{z}}^{^{m}}^{(k}^{ₓ}^{,k}^{_{y}}^{)Δz} in (4) by analytical reflection coefficients rₘ at the boundary plane z₀:

$${E}^{u p} ( x , y , {z}_{0} ) = {\sum }_{m = 1}^{M} {I}_{m}^{{z}_{0}} ( x , y ) {- 1}^{} \{ {r}_{m} ( {k}_{x} , {k}_{y} ) \{ {E}^{d o w n} ( x , y , {z}_{0} ) \} \} ,$$

where E^{up} indicates the scalar electric field at the boundary plane z₀ directed towards the structure plane 30 of the photolithography mask 14, and E^{down} indicates the scalar electric field at the boundary plane z₀ directed towards the base plane 34 of the photolithography mask 14. In this way, the computer implemented method for generating an aerial image of a model of a photolithography mask can be applied to reflection-based photolithography masks. In addition, the accuracy of the method is improved.

As shown in the article “Optical properties of a thin-film stack illuminated by a focused field” by S. Kim, Y. Kim and I. Park, Journal of the Optical Society of America A, Vol. 17, No. 8, August 2000, equations 33 to 41, the analytical reflection coefficients rₘ for each of the N optical thin films 40 of the multilayer 38 can be computed for s-polarized waves and p-polarized waves as follows:

$${r}_{j + 1}^{s} = \frac{{Y}_{j} {a}_{11} + {Y}_{j} {Y}_{N + 1} {a}_{12} - {a}_{21} - {Y}_{N + 1} {a}_{22}}{{Y}_{j} {a}_{11} + {Y}_{j} {Y}_{N + 1} {a}_{12} + {a}_{21} + {Y}_{N + 1} {a}_{22}} , {r}_{j + 1}^{p} = \frac{- {Y}_{j} {a}_{11} - {Y}_{j} {Y}_{N + 1} {a}_{12} + {a}_{21} + {Y}_{N + 1} {a}_{22}}{{Y}_{j} {a}_{11} + {Y}_{j} {Y}_{N + 1} {a}_{12} + {a}_{21} + {Y}_{N + 1} {a}_{22}}$$

where aᵢⱼ are the elements of the characteristic matrix A

$$A = [ \begin{matrix}{a}_{11} & {a}_{12} \\ {a}_{21} & {a}_{22}\end{matrix} ] = {A}_{j + 1} {A}_{j + 2} … {A}_{N} .$$

Here, Aⱼ₊₁ is given by

$${A}_{j + 1} = [ \begin{matrix}cos ( {k}_{0} {h}_{j + 1} ) & - \frac{i sin ( {k}_{0} {h}_{j + 1} )}{{Y}_{j + 1}} \\ - {Y}_{j + 1} i sin ( {k}_{0} {h}_{j + 1} ) & cos ( {k}_{0} {h}_{j + 1} )\end{matrix} ] ,$$

$$where$$

$$\begin{matrix}{h}_{j + 1} = {n}_{j + 1} {d}_{j + 1} cos {θ}_{j + 1} \\ {Y}_{j + 1} = \sqrt{\frac{{ϵ}_{0}}{{μ}_{0}}} {n}_{j + 1} cos {θ}_{j + 1} for s - polarized waves \\ {Y}_{j + 1} = \sqrt{\frac{{ϵ}_{0}}{{μ}_{0}}} \frac{{n}_{j + 1}}{cos {θ}_{j + 1}} for p - polarized waves .\end{matrix}$$

Here ∈₀ denotes the vacuum permittivity, μ₀ the vacuum magnetic permeability, nⱼ₊₁ the refractive index of the j+1-th optical thin film 40 and dⱼ₊₁ the thickness of the j+1-th optical thin film 40. Reference is hereby made in full to the aforementioned article, and its disclosure content is included in the description of this invention.

In another example, the reflection of the electromagnetic waves by the multilayer 38 could be computed numerically as follows: in a first step, the electric field at the boundary plane 32 is decomposed in its Fourier Modes. In a second step, for each Fourier mode, the reflected electromagnetic field can be computed using, for example, the transfer matrix method (described in Section 2.2 of the article “Domain Decomposition Method for Maxwell's Equations: Scattering off Periodic Structures, Achim Schädle, Lin Zschiedrich, Sven Burger, Roland Klose, Frank Schmidt, in arXiv:math/0602179v1”). In a third step, the superposition of the reflected Fourier modes yields the reflected electromagnetic waves. Alternatively, a machine learning model can be trained for numerically simulating the propagation of the electromagnetic waves within the second section of the photolithography mask.

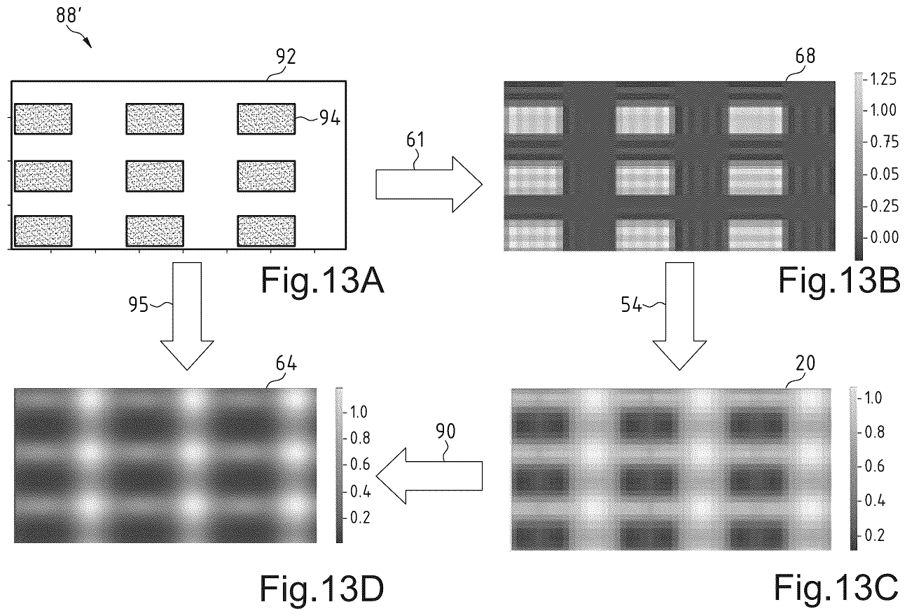

FIGS. 13A to 13D illustrate the steps of a computer implemented method 54, 54′, 54″, 54″′ for generating an aerial image 64 of a model of a photolithography mask 14 according to an embodiment of the invention. The model 92 of the photolithography mask 14 comprises elements 94 consisting of polygons in the form of rectangles shown in FIG. 13A. In a characteristic function step 61, the elements 94 are represented by characteristic functions, e.g., by binary characteristic functions 62, obtained by any of the methods described above. For example, the elements 94 are represented by binary characteristic functions 62 having the value 1 within the elements 94 and the value 0 outside. Then a spatial analytical Fourier transform is applied to the characteristic functions followed by an inverse FFT for back transformation resulting in band-limited characteristic functions 68. Here, the analytical Fourier transform is only computed for the spatial frequencies of the discretized domain of the inverse FFT. This subsampling of the spatial domain limits the maximum frequency of the characteristic functions according to the Shannon-Nyquist theorem. Thus, the discretization corresponds to a low pass filter of the characteristic functions. The result is a band-limited discretized representation of the model 92 of the photolithography mask 14, i.e., band-limited characteristic functions 68 sampled on a sampling grid of low resolution shown in FIG. 13B. Based on the band-limited characteristic functions 68 a representation of an electromagnetic near field 20 in the form of its amplitude is shown in FIG. 13C, which is simulated by propagating the simulated electromagnetic waves to a near field plane. Finally, an aerial image 64 shown in FIG. 13 [symbol] is computed 90 by applying a simulation of the imaging process of the photolithography system 10, 10′ within a projection section 19 between the near field plane 52 and a wafer plane 18 to the representation of the electromagnetic near field 20.

The imaging process can include resampling of the electromagnetic near field 20 to a grid of higher resolution. By computing the aerial image 64 by applying the characteristic function step 61 and the aerial image generation step 63 an accurate aerial image 64 can be simulated for the model 92 of the photolithography mask 14 at low computation times due to the low resolution of the sampling grid. Thus, the computation time for obtaining the aerial image 64 is reduced compared to the simulation of an aerial image 64 by applying a rigorous simulation method (such as RCWA) to the model 92, e.g., design pattern, of the photolithography mask 14 in a rigorous simulation step 95, which requires a sampling grid of high resolution.

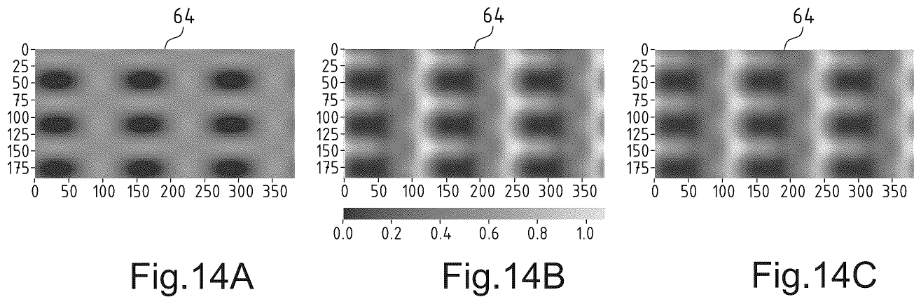

FIGS. 14A to 14C show a comparison of aerial images 64 of a model of a photolithography mask 14 obtained by three different simulation methods. All three figures show the intensity distribution of the obtained aerial images 64. FIG. 14A shows the aerial mage 64 simulated using the TEA method described above. FIG. 14B shows the aerial image 64 generated using a computer implemented method for generating an aerial image 64 of a model of a photolithography mask 14 as described above. FIG. 14C shows an aerial image 64 simulated by a rigorous simulation method, the RCWA method described above. The results show that a computer implemented method 54, 54′, 54″, 54″′ for generating an aerial image 64 of a model of a photolithography mask 14 approximates the true aerial image 64 with a very low error rate and, thus, is more accurate than the TEA method.

The computation times of the above-described methods can be even further reduced using acceleration methods known to the person skilled in the art, for example graphics processing units (GPUs), distributed GPUs, field programmable gate arrays (FPGA), etc.

The computation time for the TEA method in FIG. 14A is 0.4 seconds. The computation time for the computer implemented method 54, 54′, 54″, 54″′ for generating an aerial image 64 in FIG. 14B is between 0.01 and 0.4 seconds depending on the grid structure. If the edges of the model 92, e.g., design pattern, are aligned with the FFT grid the computation time is around 0.01 seconds. However, in general, the model 92, e.g., design pattern, is provided in terms of elements 94 that are not aligned with the grid used in the FFT. In this case, the Fourier Transform is applied to the elements 94 to map the characteristic functions to the FFT grid, which requires computation times around 0.4 seconds. The computation time for the rigorous simulation method, the RCWA method, in FIG. 14C, is between 10 and 1000 seconds depending on the smallest feature size, e.g., a defect size. Thus, computer implemented methods according to the embodiment of the invention yield approximations of the aerial image 64 with a very low error rate at computation times comparable to common aerial image approximation methods. Compared to rigorous simulation methods, the methods according to an embodiment of the invention are about two to four orders of magnitude faster at an error level of a few percent only.

For many applications, a comparison of a generated aerial image and a reference aerial image is carried out. The reference aerial image can, for example, be an acquired aerial image (called die-to-die mode) or a simulated aerial image (called die-to-database mode). In order to obtain meaningful results from such a comparison, the generated aerial image must be highly accurate and exactly replicate the reference aerial image, e.g., the reference aerial image acquisition conditions. To this end, a calibration of the generated aerial image is advantageous.

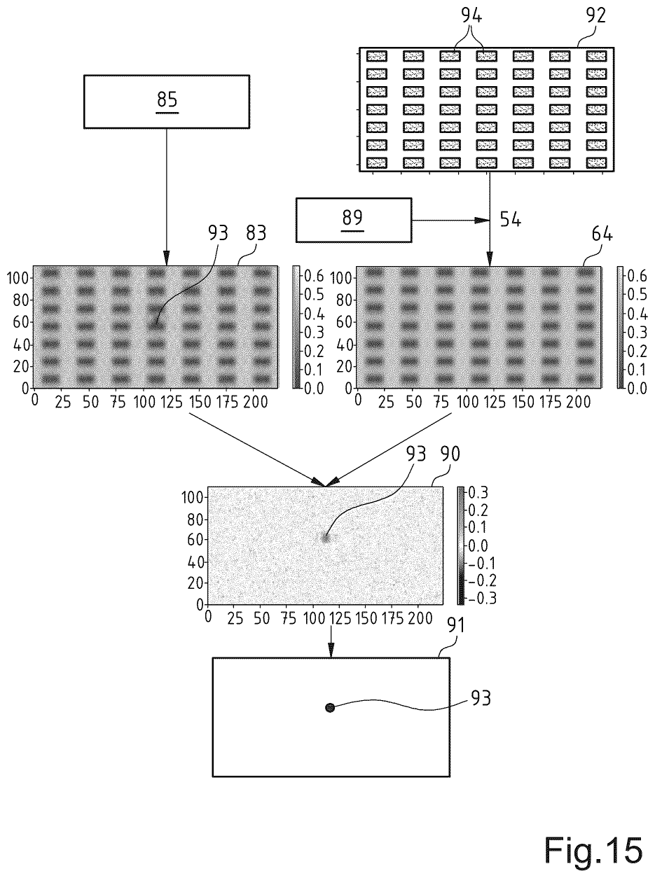

In an example illustrated in FIG. 15, defects 93 are detected by comparing an obtained aerial image 83, here an acquired aerial image that was acquired using some metrology system 85, to a simulated aerial image 64. The obtained aerial image 83 contains a defect 93. The simulated aerial image 64 is generated using a method 54, 54′, 54″, 54″′ for generating an aerial image 64 of a model 92 of a photolithography mask according to an embodiment, example or aspect of the invention described above. In this way, the simulated aerial image 64 is generated accurately and at low computation time. The obtained aerial image 83 is compared to the simulated aerial image 64, e.g., by subtracting the images, thereby generating a comparison result 90. From the comparison result 90 a defect map 91 is generated that indicates the location of the defect 93, e.g., by use of thresholding, adaptive thresholding or by applying a machine learning method for defect detection.

In order to be able to compare the obtained aerial image 83 obtained by the metrology system 85 to the simulated aerial image 64 using a method 54, 54′, 54″, 54′″ according to the invention, it is important to consider properties of the metrology system 85 and the photolithography mask when generating the aerial image 64 from the model 92 of the photolithography mask. Properties of the metrology system 85 to consider comprise, for example, the illumination setting, the imaging setting, a sensor model, motion blur due to scanning, field-dependent effects, defocus, distortions, aberrations, apodizations, etc. Properties of the mask to consider comprise, for example, a bias, corner rounding, a side wall angle, layer heights, refractive indices, etc., as described above in more detail. To consider these properties, the method for generating an aerial image of a model of a photolithography mask can comprises mask parameters and/or optical parameters as described above that can be adjusted.

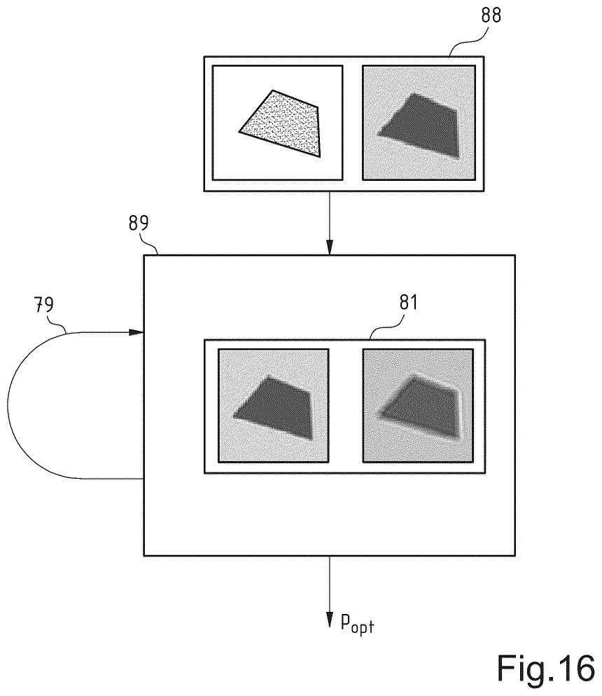

Thus, in a preferred embodiment, the method 54, 54′, 54″, 54″′ for generating an aerial image 64 from a model 92 of a photolithography mask further comprises adjusting at least one parameter of the method to minimize dissimilarities between one or more reference aerial images 88 of one or more photolithography masks and corresponding generated aerial images 64 of corresponding models 92 of the one or more photolithography masks, wherein the at least one parameter is from the group comprising mask parameters and optical parameters. These parameter adjustments can be carried out in a calibration step 89 that is shown in detail in FIG. 16.

The calibration step 89, as illustrated in FIG. 16, comprises adjusting parameters p of the method 54 for generating an aerial image of a model of a photolithography mask by minimizing dissimilarities between one or more reference aerial images 88 and corresponding generated aerial images 64. The one or more reference aerial images 88 can, for example, comprise acquired aerial images that were acquired by the metrology system 85 for one or more photolithography masks. The corresponding generated aerial images 64 can, for example, be generated using an embodiment of the method for generating an aerial image using corresponding models 92 of the one or more photolithography masks. Other methods for generating an aerial image from a model of a photolithography mask can also be used. However, the method according to the invention has the advantage that it is fast, accurate and allows the computation of gradients, which greatly simplifies the optimization of the method parameters. The one or more reference images 88 can comprise the acquired aerial image of the model 92 of the photolithography mask that is to be examined for defects 93.

The parameters p of the method 54 including mask parameters and/or optical parameters can, for example, be optimized 81 in an iterative way 79 including a single or multiple iterations as illustrated in FIG. 16 To this end, an optimization problem such as the following can be solved:

$${p}_{opt} = arg {min}_{p} χ [ {I}_{a c q} , {I}_{g e n} ( p ) , p ] .$$

pₒₚₜ is the target parameter vector that minimizes a difference measure x Between an acquired aerial image I_{acq} and a generated aerial image I_{gen}. x is an objective function or loss function that defines the optimality condition. It can be linked to a noise model of the acquired aerial image, e.g., for Gaussian i.i.d. noise the L₂-norm can be used. The objective function may also include additional regularization terms as functions of p, in particular to obtain a well-posed objective function.

Different approaches are known for computing the intensity of the generated aerial image I_{gen} using partially coherent imaging and incoming electromagnetic near fields corresponding to different illumination angles in step d) of the method, for example the Hopkins approach, the Abbe approach and the local Hopkins approach.

The Hopkins approach relies on the observation that for small variations of the incidence angles of the light waves only very small deviations of the intensity, phase and polarization of the light waves can be expected. Thus, a change in the illumination angle approximately only results in a frequency shift of the respective diffraction spectrum of the photolithography mask. The same mask spectrum [symbol] {Eⁱⁿ(x, y)} of an incoming electromagnetic near field Eⁱⁿ(x, y) is, therefore, used for all illumination angles with a shift according to the illumination angle:

$${I}^{out} ( {x}^{′} , {y}^{′} , p ) = 0.5 {∈}^{0} {c}^{0} {\sum }_{i = 1}^{{N}_{A b b e}} \hat{J} ( {f}_{x , i}^{i l l u} , {f}_{y , i}^{i l l u} , p ) {\vert {- 1}^{} \{ \{ {E}^{i n} ( x , y ) \} ( {f}^{x} - {f}_{x , i}^{i l l u} , {f}^{y} - {f}_{y , i}^{i l l u} , p ) \hat{P} ( {f}^{x} , {f}^{y} , p ) \} \vert}^{2} ,$$

where I^{out}(x′, y′) indicates the intensity of the aerial image, \hat{P}(f^{x}, f^{y}) a complex imaging pupil function, Ĵ(f_{x,i}^{illu}, f_{y,i}^{illu}) an illumination angle weighting distribution (e.g., with respect to the illumination intensity), ∈⁰ the electric permittivity, c⁰ the speed of light assuming vacuum, f_{x,i}^{illu}, f_{y,i}^{illu} the illumination angles and N_{Abbe} the number of illumination angles in the illumination angle distribution in the pupil plane.

This approach is simple and fast. For simulations using the thin mask or Kirchhoff approach such as the TEA this assumption is always fulfilled. However, in case that the thickness of the structures on the photolithography mask cannot be neglected anymore and require rigorous electromagnetic field simulations of mask diffraction for varying illumination angles, the Hopkins approach is not sufficiently accurate.

In this case the Abbe approach may be used to accommodate for the non-constant diffraction spectra of the photolithography mask, since the Abbe approach assumes illumination angle dependent diffraction spectra [symbol] {E^{in,i}}, i=1, . . . N_{Abbe}:

$${I}^{out} ( {x}^{′} , {y}^{′} , p ) = 0.5 {∈}^{0} {c}^{0} {\sum }_{i = 1}^{{N}_{A b b e}} \hat{J} ( {f}_{x , i}^{i l l u} , {f}_{y , i}^{i l l u} , p ) {\vert {- 1}^{} \{ \{ {E}^{i n , i} ( x , y ) \} ( {f}^{x} , {f}^{y} , p ) \hat{P} ( {f}^{x} , {f}^{y} , p ) \} \vert}^{2} ,$$

However, the Abbe approach is highly computationally expensive, since an electromagnetic near field has to be simulated for every single illumination angle. Thus, the Abbe approach may not be suitable for use in, e.g., a simulation of a full-chip capable optical proximity correction (OPC) or verification system.

In order to obtain a fast and accurate simulation method for aerial images of photolithography masks, the local Hopkins approach can be used as disclosed, for example, in US 2007/0253637 A1. The local Hopkins approach is a combination of the Hopkins approach and the Abbe approach based on locally assuming constant diffraction spectra of the photolithography mask. To this end, the source maps are partitioned into a number of segments. For each segment the diffraction spectra are assumed constant, such that only a single diffraction spectrum for each segment has to be simulated. Hence, with the local Hopkins approach, a smaller number of spectra [symbol] {E^{in,j}}, j=1, . . . N_{Hop}, N_{Hop}«N_{Abbe}, for a subset of selected illumination angles is simulated. For the remaining illumination angles the simulated spectra are shifted according to the illumination angle:

$${I}^{out} ( {x}^{′} , {y}^{′} , p ) = 0.5 {∈}^{0} {c}^{0} {\sum }_{j = 1}^{{N}_{Hop}} {\sum }_{i = 1}^{{N}_{Abbe , j}} \hat{J} ( {f}_{x , i}^{i l l u} , {f}_{y , i}^{i l l u} , p ) {\vert {- 1}^{} \{ \{ {E}^{i n , j} ( x , y , p ) \} ( {f}^{x} - Δ {f}_{x , i , j}^{i l l u} , {f}^{y} - Δ {f}_{y , i , j}^{i l l u} ) \hat{P} ( {f}^{x} , {f}^{y} , p ) \} \vert}^{2} ,$$

$$where Δ {f}_{x , i , j}^{i l l u} = {f}_{x , i}^{i l l u} - {f}_{x , i , j}^{i llu , Hop} and Δ {f}_{y , i , j}^{i l l u} = {f}_{y , i}^{i l l u} - {f}_{y , i , j}^{i llu , Hop} .$$

The local Hopkins approach requires a careful selection of segments and illumination angles within the segments, for which the diffraction spectra are simulated, as, for example, described in US 2007/0253637 A1.

The Hopkins, Abbe or local Hopkins approach allows to compute the gradient with respect to the parameter vector p. Thus, by using one of these approaches to compute the generated aerial image I_{gen} from the electromagnetic near field in the objective function x above, the parameters p can be optimized in an iterative way, e.g., by use of gradient descent. Note that, contrary to mask parameters (e.g., bias. corner-rounding, etc.), the optimization of optical parameters (e.g., Zernike aberrations) which can be modelled by changes in the pupil function, do not require new simulations of the electromagnetic near field but just a re-evaluation of the Hopkins, Abbe or local Hopkins approach, thereby simplifying and speeding up the optimization of the parameter vector p.

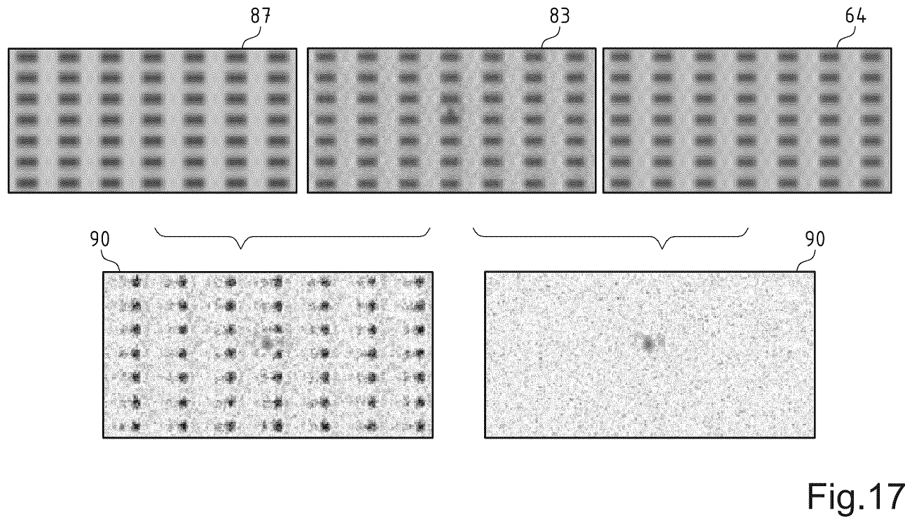

FIG. 17 illustrates the benefits of adjusting mask and optical parameters of the method for generating an aerial image of a model of a photolithography mask. In the center of the top row, an obtained aerial image 83 for a given photolithography mask is shown. The obtained aerial image 83 can be an acquired aerial image using a metrology system. On the left in the top row, a generated aerial image without calibration 87 is shown that is obtained by applying a method for generating an aerial image of a model of a photolithography mask according to the invention to a model of the photolithography mask without performing the calibration step 89. On the right in the top row, a generated aerial image 64 including calibration is shown that is obtained by applying a method for generating an aerial image of a model of a photolithography mask according to the invention to a model of the photolithography mask and performing the calibration step 89. In the bottom row, comparison results 90, i.e., difference images, are presented that clearly show the benefit of the additional calibration step 89.

For mask analysis, metrology systems often compare positions of structures in reference aerial images, e.g., acquired aerial images, to the corresponding positions in generated aerial images. To this end, a high precision of the reference aerial images is required, e.g., a subpixel accuracy approximately below 1 nm. However, structure positions cannot be directly estimated from the reference aerial images due to a low-pass filtering effect of the numerical aperture and due to mask 3D effects or optical proximity effects that lead to displacements of structures in the aerial images. In addition, reference aerial images of the metrology systems often suffer from aberrations and further image error sources, e.g., distortions, apodizations, noise (e.g., shot noise, read-out noise, etc.), etc.

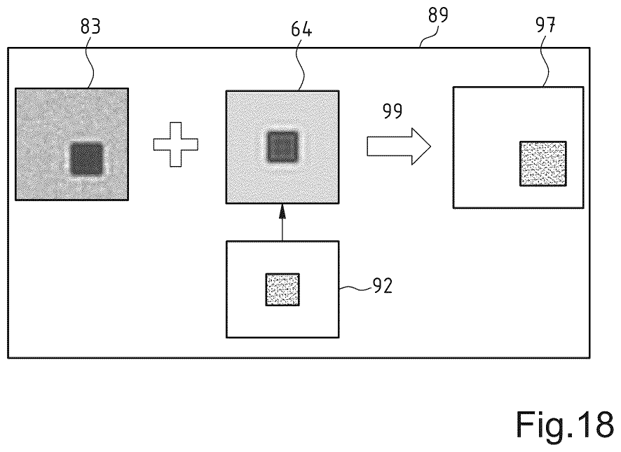

Therefore, according to an example illustrated in FIG. 18, the method for generating an aerial image of a model 92 of a photolithography mask further comprises registering 99 one or more obtained aerial images 83, e.g., acquired aerial images, of the photolithography mask to corresponding generated aerial images 64 of the model 92 of the photolithography mask, and reporting at least one registration parameter. The registration 99 can also be understood as a calibration step 89 or as a part of the calibration step 89. In this way, displacements of structures are reduced and the defect detection is improved. In FIG. 18, the obtained aerial image 83 on the left is an acquired aerial image of a photolithography mask using a metrology system. It is registered 99 to a generated aerial image 64 that is generated from the underlying model 92 of the photolithography mask. The registration result 97 is indicated on the right.

For registering aerial images, various registration methods can be used. For example, (sub-pixel) shifts of one of the aerial images can be optimized, e.g., by minimizing an error norm such as an L₂ norm or a Huber loss, or by maximizing a similarity measure such as a cross-correlation of the aerial images. Note that subpixel shifts for a Nyquist-sampled simulated (noise-free) reference image is exact when using sinc-interpolation (Fourier shifts) and neglecting boundary effects. Non-linear registration methods can also be used. For example, continuous optimization methods can be used for registration, e.g., in a variational approach. Further constraints can be imposed on the registration result. Different registration methods with subpixel accuracy are, for example, described in “Efficient subpixel image registration algorithms, Manuel Guizar-Sicairos, Samuel T. Thurman, and James R. Fienup, Opt. Lett. 33, pp. 156-158, 2008”.

Apart from registration parameters, critical dimension (CD) parameters could also be estimated by the optimization method. The CD can be a global parameter (constant over the entire model) or a local parameter (locally varying over the model) of the mask model and the loss function.

According to an example, the one or more obtained aerial images 83 comprise a focus stack of a photolithography mask. The focus stack includes a plurality of aerial images for the same measurement site obtained at different focus settings. The focus stack can be used in different ways. For example, a best focus aerial image could be interpolated from the focus stack, and this best focus aerial image could be registered to the generated aerial image 64 of the model 92 of the photolithography mask during registration. Alternatively, all of the aerial images in the focus stack can be taken into account during registration, e.g., by computing the norm of the complete difference image stack during optimization.

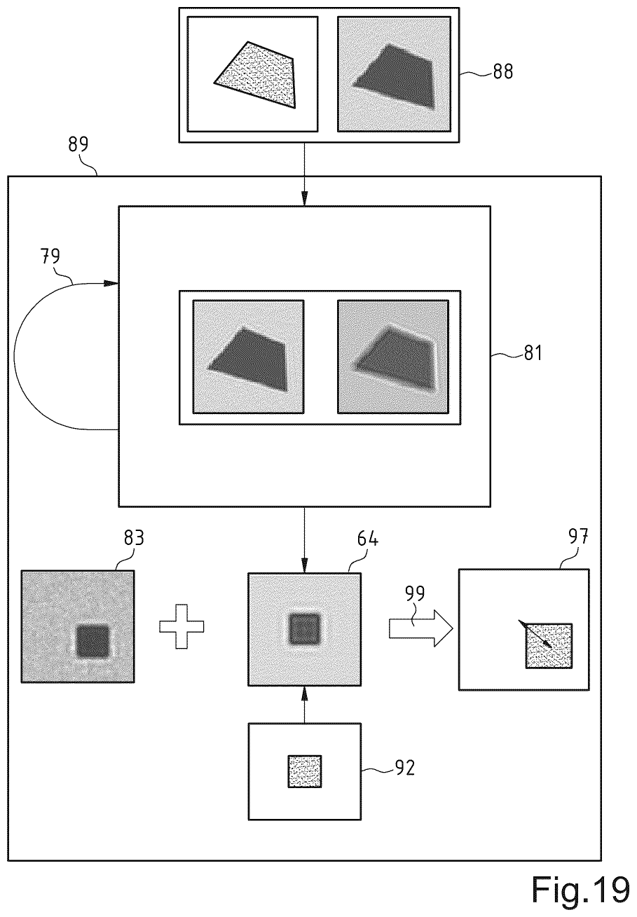

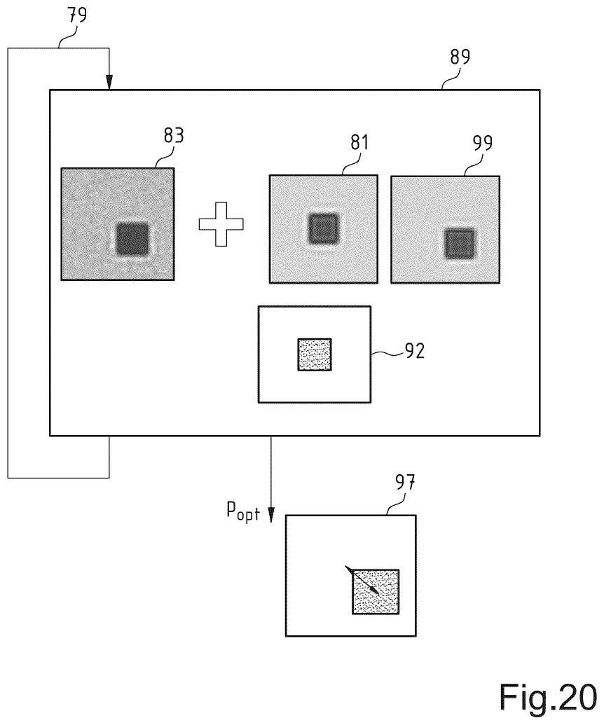

In an example, the calibration step 89 comprises both, the optimization 81 of the mask and optical parameters and the registration 99. In one example illustrated in FIG. 19, the optimization 81 can be carried out prior to the registration 99. The aerial image 64 is then generated using the optimized mask and optical parameters. In another example illustrated in FIG. 20, the mask parameters and/or optical parameters and/or registration parameters are optimized jointly in an iterative 79 way using a single or multiple iterations. In each optimization step, the mask and optical parameters of the generated aerial image 64 are optimized 81 followed by a registration 99 of the optimized aerial image to the obtained aerial image 83. Finally, the optimized mask and optical parameters pₒₚₜ and the complete registration are reported. By optimizing the parameters in a joint approach, results of higher accuracy are obtained. For example, parameter drifts are taken into account in this way, since the parameters are optimized based on the latest measurements.

The generated aerial images of models of photolithography masks obtained according to an embodiment, example or aspect of the invention as described above can be used to advantage in the training of machine learning models.

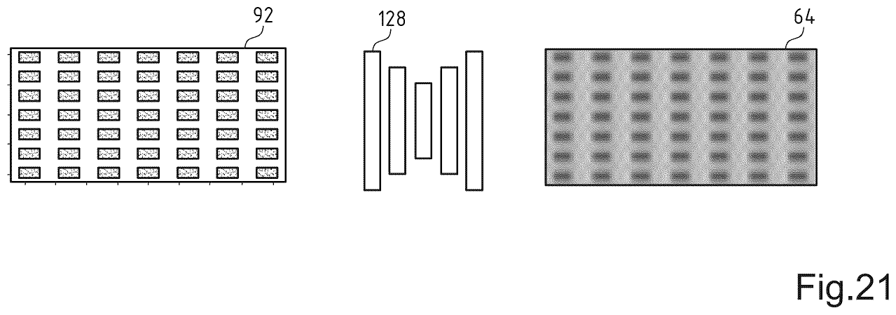

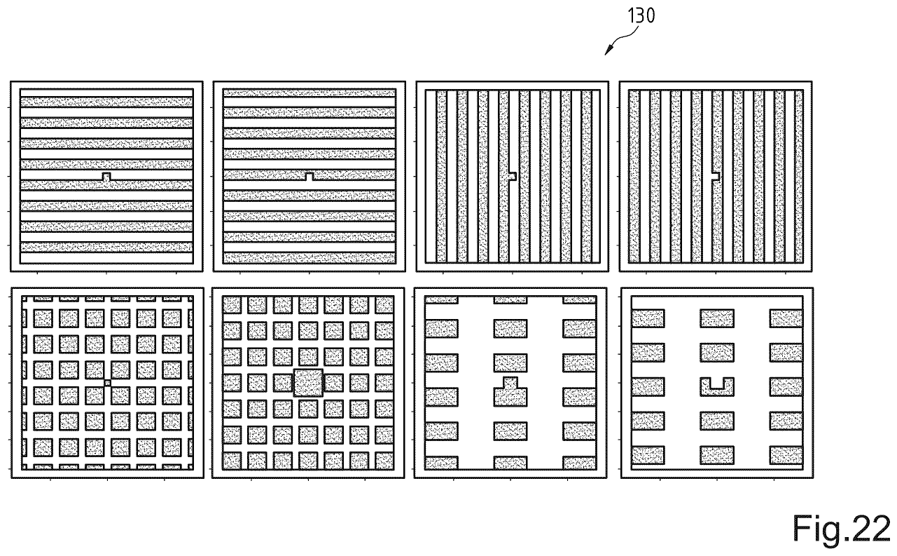

Due to the huge size of a photolithography mask compared to the wavelength, e.g., about 10⁷λ×10⁷λ for an EUV photolithography mask, generating an aerial image of a complete photolithography mask is very time-consuming—even when using a method according to the invention described above, Therefore, according to an embodiment of the invention, a machine learning model is trained to imitate the mapping from a model of a photolithography mask to an aerial image. The machine learning model is even faster than the methods according to the invention. In an example illustrated in FIG. 21, a computer implemented method for training a machine learning model 128 that maps a model 92 of a photolithography mask to an aerial image 64 of the photolithography mask, comprises: generating aerial images 64 of models 92 of multiple photolithography masks using a method for generating an aerial image of a model of a photolithography mask 54 according to any one of the embodiments, examples or aspects described above; and training the machine learning model 128 using training data comprising the generated aerial images 64. By using a method for generating an aerial image of a model of a photolithography mask 54 according to any one of the embodiments, examples or aspects described above, aerial images 64 for various models 92 of photolithography masks can be generated accurately and quickly. Using the models 92 and the generated aerial images 64 as training data, a machine learning model 128 that imitates the method for generating an aerial image of a model of a photolithography mask can be trained efficiently. The trained machine learning model 128 can then be used to generate aerial images 64 of models 92 of photolithography masks quickly. The machine learning model can, for example, comprise a neural network, e.g., a deep learning model. As only a single forward pass is required during inference, the trained machine learning model 128 requires very low computation times. FIG. 22 illustrates sample models 92 of photolithography masks that can be used for generating the training data. In addition to the generated training data, other training data can be used, e.g., acquired aerial images or simulated aerial images obtained by a different method. The additional training data could, for example, be considered using transfer-learning after pre-training on the generated training data.

Machine learning models are also particularly promising for other photolithography applications, e.g., for defect detection in photolithography masks, due to their high-quality results and their inference speed. However, these methods require large amounts of realistic and annotated training data that is usually not available based on acquired aerial images.

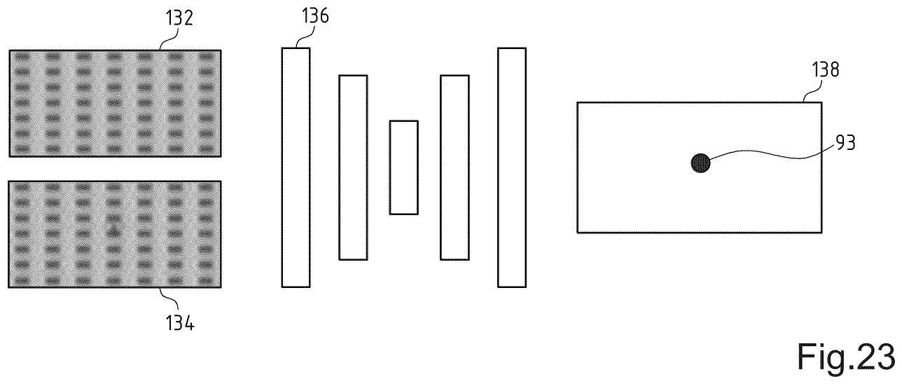

Therefore, a method for generating an aerial image of a model of a photolithography mask according to an embodiment, example or aspect of the invention described above can also be used to advantage to train machine learning models for other applications, e.g., for defect detection as illustrated in FIG. 23. The machine learning model 136 for defect detection receives a reference aerial image 132 and an acquired aerial image 134 as input that is mapped to a defect map 138 with marked defects 93 as output. The reference aerial image 132 can, for example, be an acquired aerial image (die-to-die defect detection) or a simulated aerial image (die-to-database defect detection).

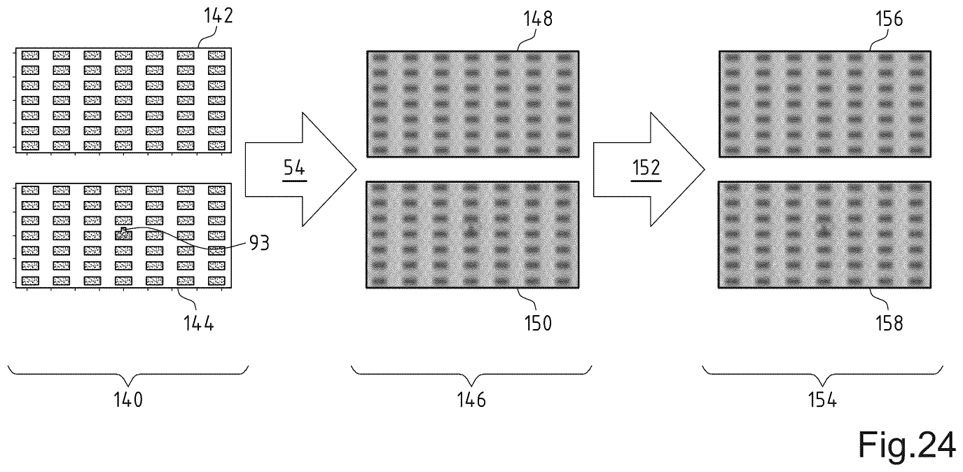

As illustrated in FIG. 24, a computer implemented method for training a machine learning model 136 for defect detection in an acquired aerial image 134 of a photolithography mask comprises: generating model pairs 140 for multiple photolithography masks, each model pair 140 containing a defect-free model 142 of a photolithography mask, i.e., a model without defect, and a defective model 144 of the same photolithography mask, i.e., a model including one or more defects 93; generating aerial image pairs 146 containing a defect-free aerial image 148 and a defective aerial image 150 of the photolithography mask from the model pairs 140 by applying a method for generating an aerial image of a model of a photolithography mask according to an embodiment, example or aspect of the invention described above to the defect-free model 142 and to the defective model 144 of each model pair 140; and training the machine learning model 136 using training data comprising the aerial image pairs 146.

Optionally, noise 152 can be added to the aerial image pairs 146, thereby generating a noisy aerial image pair 154 comprising a noisy defect-free aerial image 156 and a noisy defective aerial image 158. Noise may include realizations of all parameters that vary randomly (e.g., shot noise, readout noise, aberrations, line edge roughness, etc.) By adding noise to the aerial image pairs 146 the training data becomes more realistic, especially in case of die-to-die defect detection, which improves the training results.

In addition to the generated training data, other training data can be used, e.g., acquired aerial images or simulated aerial images obtained by a different method, e.g., defect-free acquired aerial images or simulated aerial images. The additional training data could, for example, be considered using transfer-learning after pre-training on the generated training data.

The generated aerial image of the model of the photolithography mask can be used in different ways.

For example, based on an accurate aerial image the model, e.g., design pattern, of the corresponding photolithography mask can be improved and mask 3D effects can be mitigated, e.g., by modifying the model of the photolithography mask. Alternatively, the material or thickness within the first section, e.g., the absorber material and/or absorber thickness within the grating of the photolithography mask, can be modified. Alternatively, optical proximity correction techniques can be applied to the photolithography mask, for example by adding sub resolution assist features, etc.

For example, the generated aerial image can be used for defect detection. Given an acquired or simulated aerial image of a photolithography mask, the photolithography mask can be checked for defects by generating an aerial image of the photolithography mask based on a model of the photolithography mask and by comparing the acquired or simulated aerial image to the generated aerial image.

For example, the relevance of defects in an acquired charged particle beam image of a photolithography mask can be assessed by generating an aerial image using the acquired charged particle beam image of the photolithography mask as a model of the photolithography mask and by comparing the defects in the charged particle beam image to the corresponding locations in the generated aerial image. This saves a lot of time and resources, since no aerial image of the photolithography mask needs to be acquired.

For example, the generated aerial image can be used to generate a digital twin of a machine, which uses acquired aerial images of photolithography masks. The digital twin of the machine is a digital simulation of the machine, which uses a method for generating an aerial image of a model of a photolithography mask to simulate the acquisition of an aerial image within the machine. The digital twin of the machine can be used for many different purposes, e.g., for specifying the functionality and the requirements of the machine, for presenting the functionality of the machine to the customer before the machine is built or delivered, or for accelerating the development of parts of the machine, for example of the user interface, etc.

In these applications, instead of acquiring an aerial image of the photolithography mask, a generated aerial image of a model of the photolithography mask is used, thereby considerably reducing the computation time.

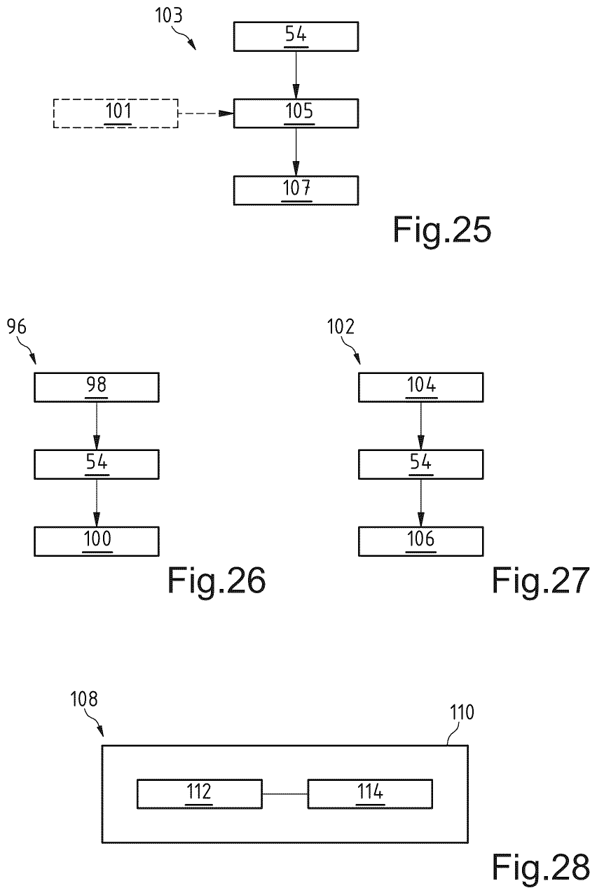

According to an embodiment illustrated in FIG. 25, a computer implemented method 103 for improving a model 92, e.g., a design pattern, of a photolithography mask 14, for repairing a photolithography mask 14, for determining the quality of a photolithography mask 14, for taking measurements of a photolithography mask 14, for detecting or assessing the relevance of defects in a photolithography mask 14, or for selecting an illumination setting in a photolithography system, comprises: generating an aerial image 64 of a model of the photolithography mask 14 using a method 54 for generating an aerial image of a model of a photolithography mask according to any of the embodiments, examples or aspects described above; analyzing the generated aerial image 64 accordingly in an analysis step 105; and improving the design of the photolithography mask 14, repairing the photolithography mask 14, determining the quality of the photolithography mask 14, detecting or assessing the relevance of defects in the photolithography mask 14, or selecting an illumination setting in a photolithography system, using the analysis results in an application step 107.

A method for improving a model 92, e.g., a design pattern, of a photolithography mask 14 may, for example, comprise generating an aerial image of the photolithography mask using a method for generating an aerial image of a model of a photolithography mask according to an embodiment, example or aspect of the invention described above. The generated aerial image may then be analyzed for defects or for a critical dimension. Based on the analysis results, the model 92 or design pattern can be improved. Then an improved photolithography mask can be manufactured from the improved model or design pattern. A method for repairing a photolithography mask may, for example, comprise acquiring an aerial image of the photolithography mask using some kind of inspection system and generating an aerial image of the photolithography mask using a method for generating an aerial image of a model of a photolithography mask according to an embodiment, example or aspect of the invention described above. By comparing the acquired aerial image to the generated aerial image defects in the photolithography mask may be detected and consecutively repaired using some kind of repair system. Based on the detected defects in the photolithography mask, a quality of the photolithograph mask may be determined. For example, the number of defects may be reported, statistics on the distribution of the defects, the severity of the detected defects, or a general quality statement such as “good”, “okay”, “must be repaired”, etc. The relevance of defects may be assessed, for example, by comparing their properties such as location, size, distribution to a predefined rules or thresholds indicating their relevance, or by simulating the printing process of the defects on a wafer and checking if the defects actually print on the wafer or not. Defects that actually print on a wafer are assessed as relevant, defects that do not print on a wafer are assessed as irrelevant. Photolithography masks comprising relevant defects may be repaired by a repair system. An illumination setting may be selected by repeatedly generating an aerial image of the photolithography mask using a method for generating an aerial image of a model of a photolithography mask according to an embodiment, example or aspect of the invention described above for different illumination settings and selecting the illumination setting leading to the aerial image of highest quality (e.g., least amount of defects, highest contrast, etc.). After identifying the best illumination setting, the current illumination setting may be modified accordingly, for example using a robot arm to change illumination settings such as aperture stops, etc.

The method can, optionally, use further information of the photolithography mask that is obtained in a further information step 101, e.g., an obtained aerial image that can be obtained using some aerial image acquisition system or metrology system or by use of simulation, or a SEM image of the photolithography mask, information on the layer dimensions, the type of mask, etc. The method can apply iterations of the aforementioned method steps, e.g., for source-mask optimization, inverse photolithography or for selecting an illumination setting. An iterative optimization, e.g., gradient-based optimization, of mask parameters or illumination parameters can be carried out that requires iterative generations of aerial images and parameter adjustments.

In order to improve a model of a photolithography mask, the analysis step 105 can comprise comparing the generated aerial image 64 of the model of the photolithography mask to an obtained aerial image, e.g., an acquired aerial image or a simulated aerial image (e.g., a simulated target aerial image), of the photolithography mask, for example to detect defects or measure critical dimensions. Based on the analysis results, the model of the photolithography mask can be modified, e.g., within the context of source-mask-optimization or inverse photolithography. Based on the analysis results, repair shapes indicating the location of defects and their correction can be generated and used to repair the photolithography mask. Based on the analysis results, the quality of the photolithography mask can be determined, e.g., by using some kind of quality measure, e.g., the number of defects, the average number of defects per area, the maximum severity of a defect, the types of defect and their frequency, etc. Based on the analysis results, defects can be detected. Based on the analysis results, the relevance of defects can be assessed by examining if a defect that is detected in the generated aerial image of the photolithography mask actually prints in the obtained aerial image of the photolithography mask or not.

Using an obtained aerial image for comparison to the generated aerial image in the analysis step 105 is optional. For example, defects can also be detected by analyzing the generated aerial image only. Measurements of the photolithography mask can be taken using the generated aerial image only. An illumination setting in a photolithography system can be selected by generating different aerial images using different illumination settings in the analysis step 105 and selecting the illumination setting that yields the aerial image of the highest quality.

The analysis step 105 can be carried out once or iteratively, e.g., during an iterative optimization. For example, during source-mask-optimization the photolithography mask can be optimized by iteratively generating an aerial image of the current model of the photolithography mask and modifying the model based on the aerial image.

FIG. 26 illustrates a computer implemented method 96 for detecting defects in a photolithography mask 14, the computer implemented method 96 comprising: obtaining an aerial image of the photolithography mask 14 in an aerial image step 98; generating an aerial image 64 of a model of the photolithography mask 14 using a computer implemented method 54, 54′, 54″, 54″′ according to the embodiment of the invention; detecting defects in the photolithography mask 14 by comparing the obtained aerial image to the generated aerial image 64 in a defect detection step 100. The aerial image of the photolithography mask can, for example, be obtained by acquiring an aerial image of the photolithography mask using an acquisition tool, or by simulating or generating an aerial image using some method, e.g., a method described above.

FIG. 27 illustrates a computer implemented method 102 for assessing the relevance of defects in a photolithography mask 14 according to an embodiment of the invention, the computer implemented method 102 comprising: providing a charged particle beam image of the photolithography mask comprising one or more defects in an imaging step 104; generating an aerial image 64 of a model of the photolithography mask using a computer implemented method 54, 54′, 54″, 54″′, wherein the charged particle beam image is used as a model of the photolithography mask 14; assessing the relevance of the one or more defects in the photolithography mask 14 using the generated aerial image 64 in an assessment step 106. A defect is assessed as relevant if it will print on the wafer during the printing process. In contrast, defects that will not print on the wafer are assessed as not relevant. The charged particle beam image is obtained by a charged particle beam device, for example, a Helium ion microscope (HIM), a cross-beam device including FIB and SEM or any charged particle imaging device. The assessment step 106 can comprise the comparison of the generated aerial image 64 to the charged particle beam image. For example, the one or more locations of the one or more defects in the charged particle beam image can be compared to the corresponding one or more locations in the generated aerial image 64. If a defect is not visible in the generated aerial image 64 it can be concluded that it does not print on the wafer and is, thus, not relevant. If a defect is visible in the generated aerial image 64 it can be concluded that it does print on the wafer and, thus, is relevant. The generated aerial image 64 can also be compared to a reference image, e.g., another generated, simulated or acquired aerial image 64 of the photolithography mask 14 to assess the relevance of the one or more defects. For example, if the generated aerial image 64 is very similar to the reference image in the location of a defect, the defect can be assessed as not relevant. If the simulated aerial image 64 differs from the reference image in the location of a defect, the defect can be assessed as relevant. The assessment step 106 can, additionally or alternatively, comprise the computation of a critical dimension (CD). The computed CD can be compared to a predefined CD. For example, if the computed CD is lower than the predefined CD in one or more locations these locations can be assessed as relevant defects.

FIG. 28 illustrates a system 108 for generating an aerial image 64 of a model of a photolithography mask 14 according to an embodiment of the invention, the system 108 comprising: a data analysis device 110 comprising at least one memory 114 and at least one processor 112 configured to perform the steps of a computer implemented method for generating an aerial image according to an embodiment of the invention described above. The processor 112 can be implemented as a central processing unit (CPU) or graphics processing unit (GPU). A CPU comprises a control unit, an arithmetic logic unit, registers and a cache. Examples of CPUs are Intel's Core i3, i5, i7 and i9 series or AMD's Ryzen series. A GPU comprises a number of processors, registers and memory blocks. Examples of GPUs are the NVIDIA Geforce RTX series, the AMD Radeon RX series or the Intel Arc series.

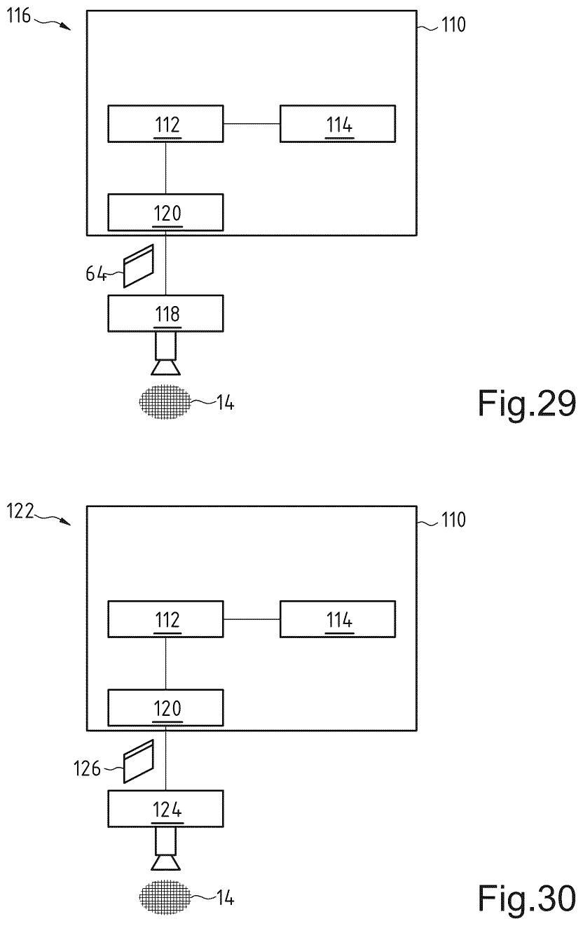

FIG. 28 also illustrates a system 108 for improving a model of a photolithography mask, for repairing a photolithography mask, for determining the quality of a photolithography mask, for taking measurements of a photolithography mask, for detecting or assessing defects in a photolithography mask, or for selecting an illumination setting for a photolithography system. It contains a data analysis device 110 comprising at least one memory 114 and at least one processor 112 configured to perform the steps of a computer implemented method for generating an aerial image of a photolithography mask according to an embodiment, example or aspect described above. The system can, optionally, also contain a subsystem for obtaining an aerial image of the photolithography mask that can be used in the analysis of the generated aerial image of the photolithography mask, e.g., for comparison, as illustrated in FIG. 29.

In some implementations, the system for repairing a photolithography mask can be configured to perform an electron beam-induced etching and/or deposition on the mask to repair defects detected by the data analysis device 110. The repair system can include, e.g., an electron source, which emits an electron beam that can be used to perform electron beam-induced etching or deposition on the mask. The repair system can include mechanisms for deflecting, focusing and/or adapting the electron beam. The repair system can be configured such that the electron beam is able to be incident on a defined point of incidence on the mask.

The repair system can include one or more containers for providing one or more deposition gases, which can be guided to the mask via one or more appropriate gas lines. The repair system can also include one or more containers for providing one or more etching gases, which can be provided on the mask via one or more appropriate gas lines. Further, the repair system can include one or more containers for providing one or more additive gases that can be supplied to be added to the one or more deposition gases and/or the one or more etching gases. The repair system can include a user interface to allow an operator to, e.g., operate the repair system and/or read out data. The repair system can also repair other types of objects (e.g., wafers) having integrated circuit patterns.

FIG. 29 illustrates a system 116 for detecting defects in a photolithography mask 14 according to an embodiment of the invention, the system 116 comprising: a subsystem 118 for obtaining an aerial image 64 of the photolithography mask 14; a data analysis device 110 comprising at least one memory 114 and at least one processor 112 configured to perform the steps of the computer implemented method 96 for detecting defects according to an embodiment of the invention. The subsystem 118 for obtaining an aerial image 64 of the photolithography mask 14 can comprise an aerial image acquisition system. Alternatively, the subsystem 118 can comprise a database or any other memory comprising an aerial image 64 of the photolithography mask 14, and the subsystem 118 can be configured to load the aerial image 64 from the database or memory. The subsystem 118 for obtaining an aerial image 64 of the photolithography mask 14 can provide an aerial image 64 to the data analysis device 110. The data analysis device 110 includes a processor 112, e.g., implemented as a CPU or GPU. The processor 112 can receive the aerial image 64 via an interface 120. The processor 112 can load program code from a memory 114, e.g., program code for executing a computer implemented method for detecting defects as described above. The processor 112 can execute the program code.

FIG. 30 illustrates a system 122 for assessing the relevance of defects in a photolithography mask 14 according to an embodiment of the invention, the system 122 comprising: a subsystem 124 for obtaining a charged particle beam image 126 of the photolithography mask 14; a data analysis device 110 comprising at least one memory 114 and at least one processor 112 configured to perform the steps of the computer implemented method 102 for assessing the relevance of defects in a photolithography mask 14 according to an embodiment of the invention. The subsystem 124 for obtaining a charged particle beam image 126 of the photolithography mask 14 can comprise a charged particle beam device, for example, a Helium ion microscope (HIM), a cross-beam device including FIB and SEM or any charged particle imaging device. Alternatively, the subsystem 124 can comprise a database or any other memory comprising a charged particle beam image 126 of the photolithography mask 14, and the subsystem 124 can be configured to load the charged particle beam image 126 from the database or memory. The subsystem 124 for obtaining a charged particle beam image 126 of the photolithography mask 14 can provide a charged particle beam image 126 to the data analysis device 110. The data analysis device 110 includes a processor 112, e.g., implemented as a CPU or GPU. The processor 112 can receive the charged particle beam image 126 via an interface 120. The processor 112 can load program code from a memory 114, e.g., program code for a computer implemented method for assessing the relevance of defects as described above. The processor 112 can execute the program code.

Embodiments, examples and aspects of the invention can be described by the following clauses:

1. A computer implemented method for simulating an electromagnetic near field of a model of a photolithography mask in a near field plane, the photolithography mask being illuminated by incident electromagnetic waves, the photolithography mask comprising a mask carrier and a grating, the grating comprising absorber structures and non-absorber structures forming a pattern on at least a portion of the mask carrier, the photolithography mask comprising a grating section extending between an absorber plane and a mask carrier plane of the photolithography mask and a mask carrier section extending between the mask carrier plane and a base plane of the photolithography mask, the method comprising:
a) Simulating the propagation of the electromagnetic waves within the grating section of the photolithography mask using a wave propagation algorithm describing the propagation of electromagnetic waves through an inhomogeneous medium;
b) Simulating the propagation of the electromagnetic waves within the mask carrier section of the photolithography mask using an analytical description of the electromagnetic wave propagation within the mask carrier; and
c) Obtaining the electromagnetic near field of the model of the photolithography mask as the simulated propagated electromagnetic waves in a near field plane next to the absorber plane of the photolithography mask.

2. The method according to clause 1, wherein the wave propagation algorithm describes a wave propagation step in a plane z₀ along the z-direction perpendicular to the base plane by

$$E ( x , y , {z}_{0} + Δ z ) = \frac{1}{2 π} \int \{ E ( x , y , {z}_{0} ) \} {e}^{i {k}_{z} ( x , y , {k}_{x} , {k}_{y} ) Δ z} {e}^{i ( {k}_{x} x + {k}_{y} y )} {dk}_{x} {dk}_{y} ,$$

where E denotes the electric field component of the electromagnetic field and (kₓ, k_{y}, k_{z})^{T} the wave vector, which locally obeys the dispersion relation

$${k}_{z} ( x , y , {k}_{x} , {k}_{y} ) = \sqrt{{k}_{0}^{2} {n ( x , y , {z}_{0} )}^{2} - {k}_{x}^{2} - {k}_{y}^{2}}$$

where

$${k}_{0} = \frac{2 π}{λ}$$

denotes the wavenumber of light with a wavelength λ in vacuum, n(x, y, z) the local refractive index, and [symbol] the Fourier transform.

3. The method according to clause 2, further comprising
a) Identifying a number M of materials of the absorber structures and the non-absorber structures forming the pattern of the photolithography mask;
b) defining a characteristic function Iₘ^{z}^{₀}:X×Y→ [symbol] for each material m∈{1, . . . , M} indicating the presence of the material for locations (x,y) of the photolithography mask within a subset X×Y⊆ [symbol] × [symbol] of an x/y-plane at z=z₀, wherein the x/y-plane is orthogonal to the z-direction;
c) Simulating the propagation step of the electromagnetic waves as a weighted sum over a propagation step within each of the identified materials:

$$E ( x , y , {z}_{0} + Δ z ) = {\sum }_{m = 1}^{M} {I}_{m}^{{z}_{0}} ( x , y ) {- 1}^{} \{ {e}^{i {k}_{z}^{m} ( {k}_{x} , {k}_{y} ) Δ z} \{ E ( x , y , {z}_{0} ) \} \} ,$$

where [symbol] ⁻¹ indicates the inverse Fourier Transform.

4. The method according to clause 3, wherein the value range [symbol] of at least one characteristic function comprises at least one value Iₘ^{z}^{₀}(x, y)∉{0,1}.

5. The method according to clause 3 or 4, wherein the characteristic functions form a convex combination at each location of the photolithography mask at z=z₀:

$${\sum }_{m = 1}^{M} {I}_{m}^{{z}_{0}} ( x , y ) = 1 ∀ ( x , y ) ∈ X \times Y$$

6. The method according to any one of clauses 3 to 5, wherein the characteristic functions are band-limited.

7. The method according to any one of clauses 3 to 6, wherein obtaining the characteristic functions comprises decomposing the pattern of the photolithography mask into polygons, representing the polygons by characteristic functions, in particular by binary characteristic functions, and applying a low pass filter to the characteristic functions.

8. The method according to clause 7, wherein applying the low pass filter comprises applying the spatial analytical Fourier transform to the characteristic functions followed by an inverse Fast Fourier Transform.

9. The method according to any one of clauses 3 to 8, wherein the analytical Fourier Transform used in the wave propagation algorithm is approximated by a Fast Fourier Transform.

10. The method according to clause 9, wherein the wave propagation algorithm takes into account the angle ϕ of the incident electromagnetic waves with respect to the normal of the absorber plane by assuming quasiperiodic boundary conditions in the Fast Fourier Transform in one or more directions perpendicular to the base plane of the photolithography mask.

11. The method according to clause 9 or 10, wherein the dispersion relation

$${k}_{z} ( x , y , {k}_{x} , {k}_{y} ) = \sqrt{{k}_{0}^{2} {n ( x , y , {z}_{0} )}^{2} - {k}_{x}^{2} - {k}_{y}^{2}}$$

is reformulated using the Floquet theorem.

12. The method according to any one of clauses 9 to 11, wherein the electromagnetic waves within the grating section have a dispersion relation depending on the angle ϕ of the incident electromagnetic waves with respect to the normal of the absorber plane in one or more directions perpendicular to the base plane of the photolithography mask.

13. The method according to any one of clauses 9 to 12, wherein the dispersion relation within the grating section is modified as follows using a phase shift vector α=(αₓ, α_{y})^{T} depending on the angle ϕ:

$${k}_{z} ( x , y , {k}_{x} - {α}_{x} , {k}_{y} - {α}_{y} ) = \sqrt{{k}_{0}^{2} {n ( x , y , {z}_{0} )}^{2} - {( {k}_{x} - {α}_{x} )}^{2} - {( {k}_{y} - {α}_{y} )}^{2}}$$

14. The method according to any one of the preceding clauses, wherein the simulated electromagnetic waves are incident on the base plane, propagated within the mask carrier section of the photolithography mask from the base plane to the mask carrier plane, and within the grating section of the photolithography mask from the mask carrier plane to the absorber plane.

15. The method according to any one of the preceding clauses, wherein the mask carrier comprises a multilayer in the form of a stack of optical thin films for reflecting the electromagnetic waves, and wherein the simulated electromagnetic waves are incident on the absorber plane, propagated within the grating section of the photolithography mask from the absorber plane to the mask carrier plane, reflected within the multilayer in the mask carrier section of the photolithography mask and propagated within the grating section of the photolithography mask from the mask carrier plane to the absorber plane.

16. The method according to clause 15, wherein simulating the reflection of the electromagnetic waves within the multilayer comprises the analytical computation of reflection coefficients at the mask carrier plane describing the propagation of the electromagnetic waves within the stack of optical thin films of the multilayer.

17. The method of clause 16, wherein the reflection coefficients are computed separately for each medium of the absorber structures and the non-absorber structures of the grating at the location of the mask carrier plane.

18. The method according to any one of clauses 3 to 13, wherein the mask carrier comprises a multilayer in the form of a stack of optical thin films for reflecting the electromagnetic waves, and
wherein the simulated electromagnetic waves are incident on the absorber plane, propagated within the grating section of the photolithography mask from the absorber plane to the mask carrier plane, reflected within the multilayer in the mask carrier section of the photolithography mask and propagated within the grating section of the photolithography mask from the mask carrier plane to the absorber plane, and
wherein simulating the reflection of the electromagnetic waves within the multilayer comprises replacing the phase term e^{ik}^{_{z}}^{^{m}}^{(k}^{ₓ}^{,k}^{_{y}}^{)Δz} by analytical reflection coefficients rₘ at the mask carrier plane z₀:

$${E}^{u p} ( x , y , {z}_{0} ) = {\sum }_{m = 1}^{M} {I}_{m}^{{z}_{0}} ( x , y ) {- 1}^{} \{ {r}_{m} ( {k}_{x} , {k}_{y} ) \{ {E}^{d o w n} ( x , y , {z}_{0} ) \} \}$$

where E^{up} indicates the scalar electric field at the mask carrier plane z₀ directed towards the absorber plane of the photolithography mask, and E^{down} indicates the scalar electric field at the mask carrier plane z₀ directed towards the base plane of the photolithography mask.

19. A computer implemented method for simulating an aerial image of a model of a photolithography mask, the method comprising:
a) A method for simulating an electromagnetic near field of the model of the photolithography mask according to any one of clauses 1 to 18;
b) Simulating an aerial image of the model of the photolithography mask by applying a simulation of the imaging process of the photolithography system within a projection section extending between the near field plane and a wafer plane to the electromagnetic near field.

20. The method according to clause 19, wherein simulating the imaging process comprises resampling of the simulated electromagnetic near field.

21. A computer implemented method for detecting defects in a photolithography mask, the method comprising:
Obtaining an aerial image of the photolithography mask;
Simulating an aerial image of a model of the photolithography mask using a method according to clause 19 or 20;
Detecting defects in the photolithography mask by comparing the obtained aerial image to the simulated aerial image.

22. A computer implemented method for assessing the relevance of defects in a photolithography mask, the method comprising:
Providing a charged particle beam image of the photolithography mask comprising one or more defects;
Simulating an aerial image of a model of the photolithography mask using a method according to clause 19 or 20, wherein the charged particle beam image is used as a model of the photolithography mask;
Assessing the relevance of the one or more defects in the photolithography mask using the simulated aerial image.

23. A computer-readable medium, having stored thereon a computer program executable by a computing device, the computer program comprising code for executing a method of any one of clauses 1 to 22.

24. A computer program product comprising instructions which, when the program is executed by a computer, cause the computer to carry out a method of any one of clauses 1 to 22.

25. A system for simulating an electromagnetic near field of a model of a photolithography mask, the system comprising a data analysis device comprising at least one memory and at least one processor configured to perform the steps of a computer implemented method according to any one of clauses 1 to 18.

26. A system for simulating an aerial image of a model of a photolithography mask, the system comprising a data analysis device comprising at least one memory and at least one processor configured to perform the steps of a computer implemented method according to clause 19 or 20.

27. A system for detecting defects in a photolithography mask, the system comprising:
a subsystem for obtaining an aerial image of the photolithography mask;
a data analysis device comprising at least one memory and at least one processor configured to perform the steps of the computer implemented method of clause 21.

28. A system for assessing the relevance of defects in a photolithography mask, the system comprising:
a subsystem for obtaining a charged particle beam image of the photolithography mask;
a data analysis device comprising at least one memory and at least one processor configured to perform the steps of the computer implemented method of clause 22.

In an aspect, the invention relates to a computer implemented method 54, 54′, 54″, 54″′ for generating an aerial image 64 of a model of a photolithography mask 14 under illumination by incident electromagnetic waves 22, the method comprising: a) Approximately simulating the propagation of the incident electromagnetic waves 22 within a first section 25 of the photolithography mask 14 that comprises multiple structures; b) Simulating the propagation of the simulated electromagnetic waves 22 from step a) within a second section 27 of the photolithography mask 14 analytically or numerically; c) Simulating a representation of an electromagnetic near field 20 of the model of the photolithography mask 14 by propagating the simulated electromagnetic waves 22 from step b) to a near field plane 52; and d) Generating an aerial image 64 of the photolithography mask 14.

Reference number list

| | |
|---|---|
| 10, 10′ | Photolithography system |
| 12 | Radiation source |
| 14 | Photolithography mask |
| 16 | Illumination optics |
| 17 | Projection optics |
| 18 | Wafer plane |
| 19 | Projection section |
| 20 | Near field |
| 22 | Electromagnetic wave |
| 24 | Grating |
| 25 | First section |
| 26 | Structures |
| 27 | Second section |
| 28 | Non-structures |
| 30 | Structure plane |
| 32 | Boundary plane |
| 34 | Base plane |
| 38 | Multilayer |
| 40 | Optical thin film |
| 42 | Capping layer |
| 44 | Effective mirror plane |
| 46 | Substrate layer |
| 48 | Mask carrier |
| 50 | Main propagation direction |
| 52 | Near field plane |
| 54, 54′, 54″, 54′″ | Computer implemented method |
| 56 | First section simulation step |
| 58 | Second section simulation step |
| 60 | Near field generation step |
| 61 | Characteristic function step |
| 62 | Binary characteristic function |
| 63 | Aerial image generation step |
| 64 | Aerial image |
| 66 | Approximation error |
| 68 | Band-limited characteristic function |
| 70 | Root mean square error |
| 72 | Maximum error |
| 74 | Root mean square error |
| 76 | Maximum error |
| 78 | Top horizontal axis |
| 79 | Iteration |
| 80 | Bottom horizontal axis |
| 81 | Optimization |
| 82 | Vertical axis |
| 83 | Obtained aerial image |
| 84 | Normal |
| 85 | Metrology system |
| 86 | Wave vector |
| 87 | Aerial image without calibration |
| 88 | Reference aerial image |
| 89 | Calibration step |
| 90 | Comparison result |
| 91 | Defect map |
| 92 | Model |
| 93 | Defect |
| 94 | Element |
| 95 | Rigorous simulation step |
| 96 | Computer implemented method |
| 97 | Registration result |
| 98 | Aerial image step |
| 99 | Registration |
| 100 | Defect detection step |
| 101 | Further information step |
| 102 | Computer implemented method |
| 103 | Computer implemented method |
| 104 | Imaging step |
| 105 | Analysis step |
| 106 | Assessment step |
| 107 | Application step |
| 108 | System |
| 110 | Data analysis device |
| 112 | Processor |
| 114 | Memory |
| 116 | System |
| 118 | Subsystem |
| 120 | Interface |
| 122 | System |
| 124 | Subsystem |
| 126 | Charged particle beam image |
| 128 | Machine learning model |
| 130 | Training models |
| 132 | Reference aerial image |
| 134 | Acquired aerial image |
| 136 | Machine learning model |
| 138 | Defect map |
| 140 | Model pair |
| 142 | Defect-free model |
| 144 | Defective model |
| 146 | Aerial image pair |
| 148 | Defect-free aerial image |
| 150 | Defective aerial image |
| 152 | Noise |
| 154 | Noisy aerial image pair |
| 156 | Noisy defect-free aerial image |
| 158 | Noisy defective aerial image |

What is claimed is:

1. A computer implemented method for generating an aerial image of a model of a photolithography mask under illumination by incident electromagnetic waves, the method comprising:
a) approximately simulating the propagation of the incident electromagnetic waves within a first section of the photolithography mask that comprises multiple structures;
b) simulating the propagation of the simulated electromagnetic waves from step a) within a second section of the photolithography mask analytically or numerically;
c) simulating a representation of an electromagnetic near field of the model of the photolithography mask by propagating the simulated electromagnetic waves from step b) to a near field plane; and
d) generating an aerial image of the photolithography mask by applying a simulation of an imaging process of a photolithography system or metrology system to the representation of the electromagnetic near field.

2. The method of claim 1, wherein the propagation of the incident electromagnetic waves within the first section of the photolithography mask in step a) is approximately simulated using a Helmholtz equation.

3. The method of claim 1, wherein the propagation of the incident electromagnetic waves within the first section of the photolithography mask (in step a) is approximately simulated using a machine learning model.

4. The method of claim 2, wherein the Helmholtz equation is approximated using a forward Helmholtz equation.

5. The method of claim 4, wherein the forward Helmholtz equation is solved using a beam propagation method.

6. The method of claim 4, wherein the forward Helmholtz equation is solved using a wave propagation method that approximately describes the propagation of electromagnetic waves through an inhomogeneous medium.

7. The method of claim 6, wherein the first section of the photolithography mask is decomposed into different materials by defining a characteristic function for each material that indicates the presence of the material within different locations in the first section of the photolithography mask, wherein at least one characteristic function is non-binary.

8. The method of claim 7, wherein the characteristic functions form an affine combination at each location in the first section of the photolithography mask.

9. The method of claim 7, wherein the characteristic functions are band-limited.

10. The method of claim 7, wherein a low pass filter is applied to the characteristic functions.

11. The method of claim 10, wherein applying the low pass filter comprises applying a spatial analytical Fourier transform to the characteristic functions followed by an inverse Fourier Transform.

12. The method of claim 6, wherein the wave propagation method approximates an analytical Fourier Transform by a Fast Fourier Transform and/or an analytical inverse Fourier Transform by a Fast Inverse Fourier Transform.

13. The method of claim 12, wherein the wave propagation method approximates an analytical Fourier Transform by a Fast Fourier Transform, and wherein the wave propagation method takes into account the angle of the incident electromagnetic waves by assuming quasiperiodic boundary conditions in the Fast Fourier Transform at one or more pairs of opposite boundaries perpendicular to a base plane of the photolithography mask.

14. The method of claim 13, wherein the electromagnetic waves within the first section have a dispersion relation that depends on the angle of the incident electromagnetic waves.

15. The method of claim 14, wherein the dispersion relation within the first section is modified by a phase shift in the coordinates parallel to the base plane of the photolithography mask.

16. The method of claim 1, wherein the photolithography mask is a transmission-based photolithography mask.

17. The method of claim 1, wherein the photolithography mask is a reflection-based photolithography mask, and wherein the second section comprises a multilayer in the form of a stack of optical thin films for reflecting the electromagnetic waves.

18. The method of claim 17, wherein simulating the reflection of the electromagnetic waves within the multilayer comprises the analytical or numerical computation of reflection coefficients at a boundary between the second section and the first section of the photolithography mask, the reflection coefficients describing the propagation of the electromagnetic waves within the stack of optical thin films of the multilayer.

19. The method of claim 18, wherein the reflection coefficients at the boundary are computed separately within the structures and outside the structures in the first section of the photolithography mask.

20. The method of claim 18, wherein simulating the propagation of the simulated electromagnetic waves within the second section of the photolithography mask comprises applying the reflection coefficients to the electromagnetic waves incident on the boundary.

21. The method of claim 1, further comprising adjusting at least one parameter of the method to minimize dissimilarities between one or more reference aerial images of one or more photolithography masks and corresponding generated aerial images of corresponding models of the one or more photolithography masks, wherein the at least one parameter is from the group comprising mask parameters and optical parameters.

22. The method of claim 1, further comprising registering one or more reference aerial images of the photolithography mask to corresponding generated aerial images of the model of the photolithography mask, and reporting at least one registration parameter.

23. The method of claim 21, wherein the one or more reference aerial images comprise a focus stack of a photolithography mask.

24. A computer implemented method for improving the design of a photolithography mask, for repairing a photolithography mask, for determining the quality of a photolithography mask, for taking measurements of a photolithography mask, for detecting or assessing defects in a photolithography mask, or for selecting an illumination setting in a photolithography system, the method comprising:
generating an aerial image of a model of the photolithography mask using a method of claim 1;
analyzing the generated aerial image accordingly;
improving the design of the photolithography mask, repairing the photolithography mask, determining the quality of the photolithography mask, detecting or assessing defects in the photolithography mask, or selecting an illumination setting in a photolithography system, using the analysis results.

25. A computer implemented method for training a machine learning model that maps a model of a photolithography mask to an aerial image of the photolithography mask, the method comprising: generating aerial images of models of multiple photolithography masks using a method of claim 1; and training the machine learning model using training data comprising the generated aerial images.

26. A computer implemented method for training a machine learning model for defect detection in an acquired aerial image of a photolithography mask, the method comprising: generating model pairs for multiple photolithography masks, each model pair containing a defect-free model of a photolithography mask and a defective model of the same photolithography mask; generating aerial image pairs from the model pairs by applying a method of claim 1 to the defect-free model and to the defective model of each model pair; and training the machine learning model using training data comprising the aerial image pairs.

27. A computer-readable medium, having stored thereon a computer program executable by a computing device, the computer program comprising code for executing a method of claim 1.

28. A computer program product comprising instructions which, when the program is executed by a computer, cause the computer to carry out a method of claim 1.

29. A system for generating an aerial image of a model of a photolithography mask, the system comprising a data analysis device comprising at least one memory and at least one processor configured to perform the steps of a computer implemented method of claim 1.

30. A system for improving a model of a photolithography mask, for repairing a photolithography mask, for determining the quality of a photolithography mask, for taking measurements of a photolithography mask, for detecting or assessing defects in a photolithography mask, or for selecting an illumination setting for a photolithography system, the system comprising:
a data analysis device comprising at least one memory and at least one processor configured to perform the steps of the computer implemented method of claim 24.
